(19) United States
(12) Patent Application Publication
(10) Pub. No.: US 2025/0234595 A1
(43) Pub. Date: Jul. 17, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Hsien-Chih HUANG, Hsinchu City (TW); Guang-Lin CHEN, Hsinchu (TW); Pei-Yu WANG, Hsinchu City (TW); Chia-Hao YU, New Taipei City (TW); Kuo-Cheng CHIANG, Hsinchu (TW); Chih-Hao WANG, Baoshan Township (TW)

(21) Appl. No.: 18/671,162

(22) Filed: May 22, 2024

Related U.S. Application Data
(60) Provisional application No. 63/620,455, filed on Jan. 12, 2024.

(51) Int. Cl. H01L 29/423; H01L 21/8238; H01L 27/092; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/015; H10D 64/017; H10D 64/018; H10D 84/0167; H10D 84/017; H10D 84/0172; H10D 84/038; H10D 84/85

(57) ABSTRACT

Inner spacers between a source/drain region of a nanostructure transistor and sacrificial nanostructure layers of the nanostructure transistor are removed prior to formation of a gate structure of the nanostructure transistor. The sacrificial nanostructure layers are removed, and then the inner spacers are removed. The sacrificial nanostructure layers are then replaced with the gate structure of the nanostructure transistor such that the gate structure and the source/drain region are spaced apart by air gaps that result from the removal of the inner spacers. The dielectric constant (or relative permittivity) of the air gaps between the source/drain region and the gate structure is less than the dielectric constant of the material of the inner spacers. The lesser dielectric constant of the air gaps reduces the amount of capacitance between the source/drain region and the gate structure.

### CROSS-REFERENCE TO RELATED APPLICATION

This patent application claims priority to U.S. Provisional Patent Application No. 63/620,455, filed on Jan. 12, 2024, and entitled “SEMICONDUCTOR DEVICE AND METHODS OF FORMATION.” The disclosure of the prior Application is considered part of and is incorporated by reference into this patent application.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for the transistor (the current that flows through the channel of the transistor when the transistor is in an off configuration). Silicon (Si)/silicon germanium (SiGe) nanostructure transistors such as nanowires, nanosheets, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. TA-1C are diagrams of an example implementation of a fin definition process described herein.

FIG. 2 is a diagram of an example implementation of a dummy gate formation process described herein.

FIG. 3 is a diagrams of an example implementation of a source/drain recess formation process described herein.

FIGS. 4A and 4B are diagrams of an example implementation of a dummy inner spacer formation process described herein.

FIGS. 5A-5D are diagrams of an example implementation of an inner spacer formation process described herein.

FIG. 6 is a diagram of an example implementation of a source/drain region formation process and an interlayer dielectric (ILD) formation process described herein.

FIGS. 7A-7D are diagrams of an example implementation of a replacement gate (RPG) process described herein.

FIGS. 8A-8D are diagrams of an example implementation forming a semiconductor device described herein.

FIG. 9 is a diagram of an example implementation of a semiconductor device described herein.

FIG. 10 is a diagram of an example implementation of a semiconductor device described herein.

FIG. 11 is a diagram of an example implementation of a semiconductor device described herein.

FIG. 12 is a diagram of an example implementation of a semiconductor device described herein.

FIG. 13 is a diagram of an example implementation of a semiconductor device described herein.

FIG. 14 is a diagram of an example implementation of a semiconductor device described herein.

FIG. 15 is a diagram of an example implementation of a semiconductor device described herein.

FIG. 16 is a diagram of an example implementation of a semiconductor device described herein.

FIG. 17 is a diagram of an example implementation of a semiconductor device described herein.

FIG. 18 is a diagram of an example implementation of a semiconductor device described herein.

FIG. 19 is a diagram of an example implementation of a semiconductor device described herein.

FIG. 20 is a flowchart of an example process associated with forming a semiconductor device described herein.

FIGS. 21A-21E are diagrams of an example implementation of an inner spacer formation process described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As the size of a nanostructure transistor is decreased, the spacing between structures of the nanostructure transistor also decreases. The reduced spacing between the structures of the nanostructure transistor may result in an increase of capacitance in the nanostructure transistor. For example, increased cell capacitance may result between a source/drain region of the nanostructure transistor and a gate structure of the nanostructure transistor. As another example, increased parasitic capacitance may result between the gate structure and a buffer region under the source/drain region. The increased capacitance may result in reduced performance of the nanostructure transistor in that the increased capacitance may result in residual charge stored in a source/drain region and/or in a gate structure of a transistor of the nanostructure transistor, which may result in longer switching times for the nanostructure transistor (e.g., between an on state and an off state) due to an increased resistance-capacitance (RC) time constant that results from the increased capacitance.

In some implementations described herein, inner spacers between a source/drain region of a nanostructure transistor and sacrificial nanostructure layers of the nanostructure transistor are removed prior to formation of a gate structure of the nanostructure transistor. The sacrificial nanostructure layers are removed, and then the inner spacers are removed. The sacrificial nanostructure layers are then replaced with the gate structure of the nanostructure transistor such that the gate structure and the source/drain region are spaced apart by air gaps that result from the removal of the inner spacers. To form the air gaps, a porous interfacial layer is formed on the inner spacers after removal of the sacrificial layers. The inner spacers are then removed through the porous interfacial layer. The porous interfacial layer prevents the space previously occupied by the inner spacers from being filled in with the material of the gate structure and associated gate dielectric layer(s).

The dielectric constant (or relative permittivity) of the air gaps between the source/drain region and the gate structure is less than the dielectric constant of the material of the inner spacers. The lesser dielectric constant of the air gaps reduces the amount of capacitance between the source/drain region and the gate structure. The amount of cell capacitance C_{Cell} between a gate structure and the source/drain region may be represented as:

$${C}_{C e l l} = k \frac{A}{d}$$

where k represents the dielectric constant (e.g., the k value) of the media between the gate structure and the source/drain region; A represents a surface area of the interface between the gate structure and the source/drain region; and d represents the distance between the gate structure and the source/drain region. Thus, the cell capacitance C_{Cell} between a gate structure and the source/drain region may be reduced by replacing the media between the gate structure and the source/drain region with the air spacers because of the lesser dielectric constant of the air gaps. Moreover, the porous interfacial layer preventing the air gaps from being filled in with the material of the gate structure and associated gate dielectric layer(s) enables the distance between the gate structure and the source/drain region to be retrained, thereby not contributing to raising the cell capacitance. In this way, the air gaps between the gate structure and the source/drain regions may enable faster switching times to be achieved for the nanostructure transistor (e.g., between the on state and the off state) due to a reduced RC time constant for the nanostructure transistor.

FIGS. 1A-1C are diagrams of an example implementation 100 of a fin definition process described herein. The example implementation 100 includes an example of forming fin structures and associated shallow trench isolation (STI) regions for a semiconductor device 105 described herein. The semiconductor device 105 may be manufactured to include one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The example implementation 100 includes an example of forming the fin structures and the associated STI regions for the transistors of the semiconductor device 105.

FIGS. 1A-IC each illustrate a perspective view of the semiconductor device 105 and a cross-sectional view along the line A-A in the perspective view. As shown in FIGS. 1A, processing of the semiconductor device 105 is performed in connection with a semiconductor substrate 110. The semiconductor substrate 110 includes a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate.

A layer stack 115 is formed on the semiconductor substrate 110. The layer stack 115 may be referred to as a superlattice. The layer stack 115 includes a plurality of alternating layers that are arranged in a direction (e.g., the z-direction) that is approximately perpendicular to the semiconductor substrate 110. For example, the layer stack 115 includes vertically alternating layers of sacrificial nanostructure layers 120 and nanostructure channel layers 125 above the semiconductor substrate 110. The quantity of the sacrificial nanostructure layers 120 and the quantity of the nanostructure channel layers 125 illustrated in FIG. 1A are examples, and other quantities of the sacrificial nanostructure layers 120 and the nanostructure channel layers 125 are within the scope of the present disclosure.

The sacrificial nanostructure layers 120 enable a vertical distance to be defined between adjacent nanostructure channels that are formed from the nanostructure channel layers 125, and serve as placeholder layers for subsequently-formed gate structures of the transistors of the semiconductor device 105 that are formed around the nanostructure channels. The sacrificial nanostructure layers 120 include a first material composition, and the nanostructure channel layers 125 include a second material composition. In some implementations, the first material composition and the second material composition are the same material composition. In some implementations, the first material composition and the second material composition are different material compositions. As an example, the sacrificial nanostructure layers 120 may include silicon germanium (SiGe) and the nanostructure channel layers 125 may include silicon (Si). This enables the sacrificial nanostructure layers 120 and/or the nanostructure channel layers 125 to be selectively etched (e.g., enables the sacrificial nanostructure layers 120 and not the nanostructure channel layers 125 to be etched, enables the nanostructure channel layers 125 and not the sacrificial nanostructure layers 120 to be etched) depending on the type of etchant that is used.

One or more types of deposition tools may be used to deposit and/or grow the alternating layers of the layer stack 115 to include nanostructures (e.g., nanosheets) on the semiconductor substrate 110. For example, a deposition tool may be used to grow the sacrificial nanostructure layers 120 and/or the nanostructure channel layers 125 by epitaxial growth, which may include epitaxy techniques such as a molecular beam epitaxy (MBE), metalorganic chemical vapor deposition (MOCVD) process, and/or another suitable epitaxy technique. Additionally and/or alternatively, the sacrificial nanostructure layers 120 and/or the nanostructure channel layers 125 may be deposited by chemical vapor deposition (CVD), physical vapor deposition (PVD), atomic layer deposition (ALD), and/or another suitable deposition technique.

One or more masking layers may be form (e.g., using one or more deposition tools) on the layer stack 115. The masking layer(s) may include a hard mask (HM) layer 130, a capping layer 135, an oxide layer 140, and/or a nitride layer 145. Masking layer(s) may be used to perform a fin patterning operation to form fin structures in the semiconductor substrate 110.

As shown in FIG. 1B, the layer stack 115 and the semiconductor substrate 110 are etched to remove portions of the layer stack 115 and portions of the semiconductor substrate 110. This results in formation of fin structures 150 that extend above the semiconductor substrate 110. The fin structures 150 may extend in an x-direction in the semiconductor device 105 and may be arranged in ay-direction in the semiconductor device 105. A fin structure 150 includes a portion 155 of the layer stack 115 over and/or on a fin portion 160 above the semiconductor substrate 110. The fin structures 150 may be formed by patterning the one or more masking layers and etching the semiconductor substrate 110 based on a pattern formed in one or more of the masking layers. The one or more masking layers may be patterned using photolithography techniques, including double-patterning or multi-patterning techniques. An etch tool may be used to etch the semiconductor substrate 110 based on the pattern using a dry etch technique (e.g., reactive ion etching), a wet etch technique, and/or a combination thereof.

As further shown in FIG. 1B, some fin structures 150 may be formed to have different widths for different types of nanostructure transistors. As an example, a first subset of fin structures 150a may be formed for p-type nanostructure transistors (e.g., p-type metal oxide semiconductor (PMOS) nanostructure transistors), and a second subset of fin structures 150b may be formed for n-type nanostructure transistors (e.g., n-type metal oxide semiconductor (NMOS) nanostructure transistors). As another example, a first subset of fin structures 150a may be formed for nanostructure transistors that are configured to operate at lower voltages, and a second subset of fin structures 150b may be formed for nanostructure transistors that are configured to operate at higher voltages.

As shown in FIG. 1C, a liner 165 and STI regions 170 are formed between adjacent fin portions 160 of the fin structures 150. The liner 165 and the STI regions 170 may each include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material.

A deposition tool may be used to conformally deposit the liner (e.g., using ALD or another conformal deposition technique), and may deposit a dielectric layer (e.g., using CVD, PVD, a ALD, and/or another suitable deposition technique) on the liner 165 such that the dielectric layer fully fills in the spaces between the fin structures 150 and extends above the tops of the fin structures 150. A planarization tool may then be used to perform a planarization or polishing operation (e.g., a chemical mechanical planarization (CMP) operation) to planarize the dielectric layer such that the top surface of the dielectric layer is approximately co-planar with the top of the nitride layer 145. The nitride layer 145 functions as a CMP stop layer in the planarization operation. An etch tool may be used to then etch the dielectric layer to form the STI regions 170 such that the top surfaces of the STI region 170 are approximately co-planar with or below the bottom-most sacrificial nanostructure layer 120.

As indicated above, FIGS. 1A-1C are provided as an example. Other examples may differ from what is described with regard to FIGS. 1A-1C.

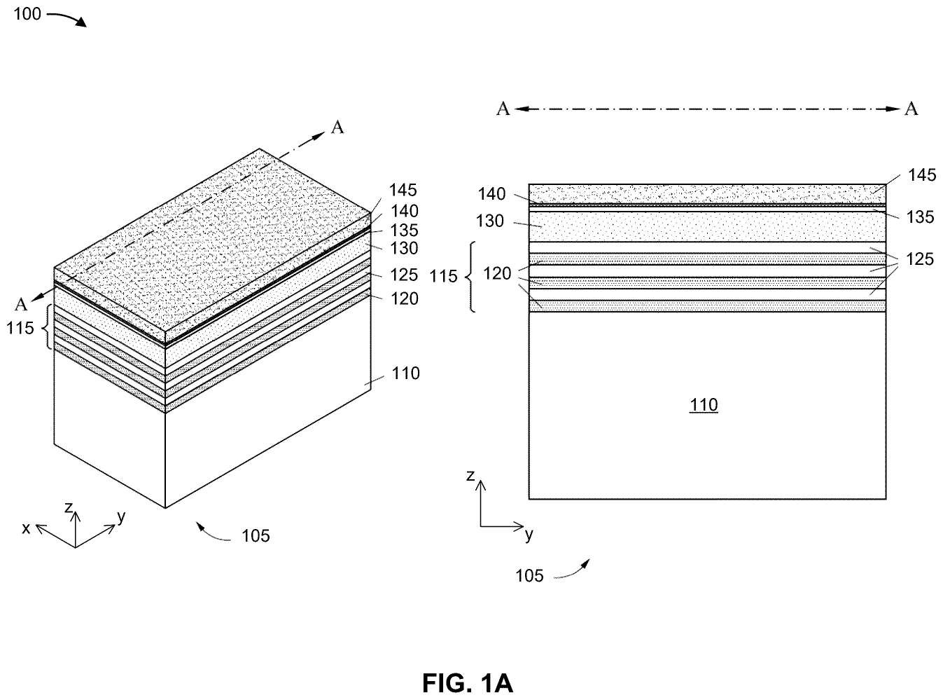

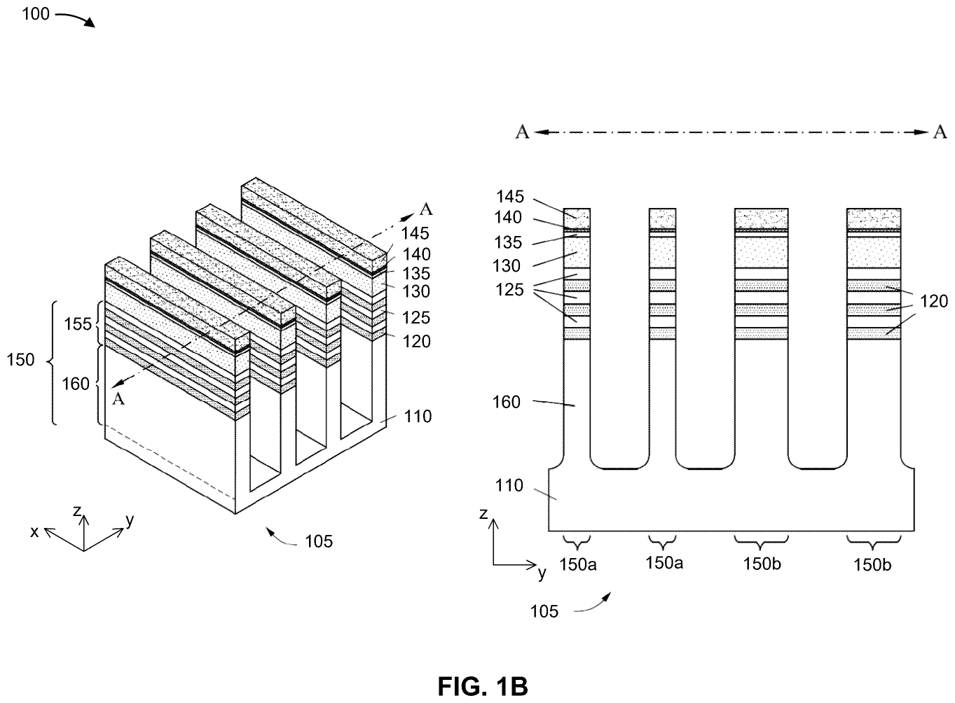

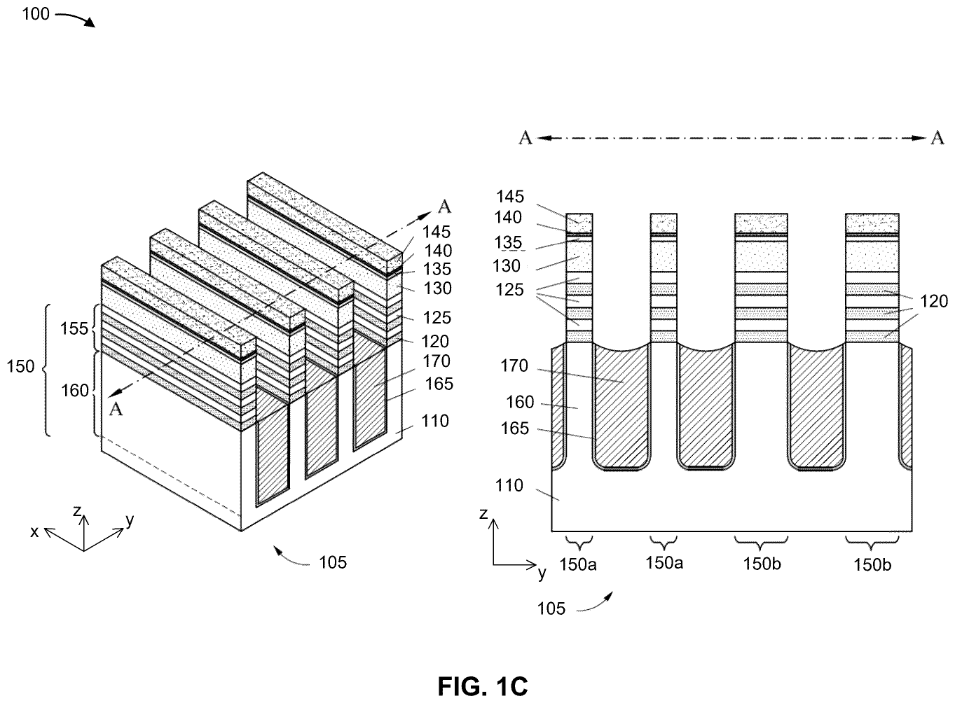

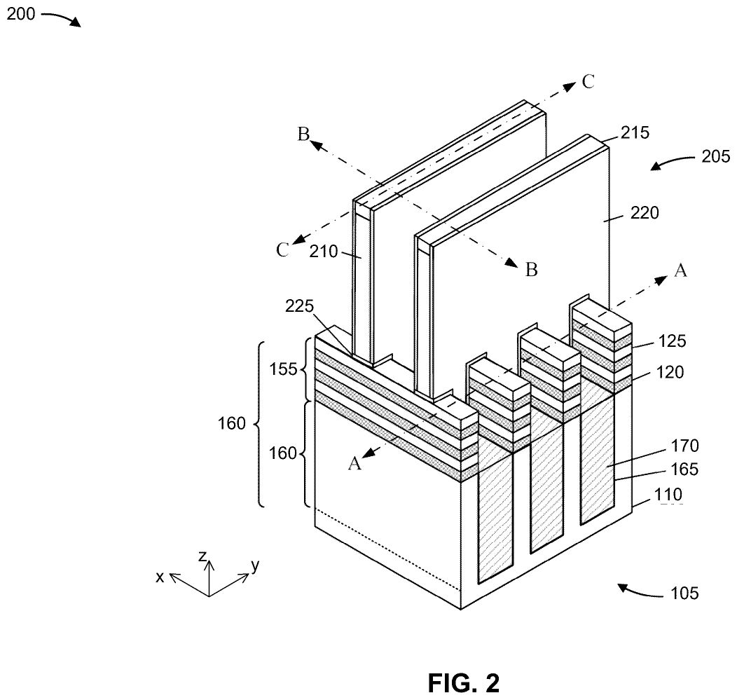

FIG. 2 is a diagram of an example implementation 200 of a dummy gate formation process described herein. The example implementation 200 includes an example of forming dummy gate structures 205 for nanostructure transistors of the semiconductor device 105. In some implementations, the operations described in connection with the example implementation 200 are performed after the processes described in connection with FIGS. 1A-1C.

FIG. 2 illustrates a perspective view of the semiconductor device 105 with the dummy gate structures 205 formed thereon. The dummy gate structures 205 (also referred to as dummy gate stacks or temporary gate structures) are formed over portions of the fin structures 150 and portions of the STI regions 170. The dummy gate structures 205 extend in the y-direction and are arranged in the x-direction such that the dummy gate structures 205 are approximately perpendicular to the fin structures 150. The dummy gate structures 205 are sacrificial structures that are to be replaced by replacement gate structures or replacement gate stacks at a subsequent processing stage for the semiconductor device 105. The dummy gate structures 205 may also be used to define source/drain (S/D) recesses in which source/drain regions of the nanostructure transistors are formed in the fin structures 150.

A dummy gate structure 205 may include a gate electrode layer 210, a hard mask layer 215 over and/or on the gate electrode layer 210, and spacer layers 220 on opposing sides of the gate electrode layer 210, and a gate dielectric layer 225 under the gate electrode layer 210. The gate electrode layer 210 includes polycrystalline silicon (polysilicon or PO) or another material. The hard mask layer 215 includes one or more layers such as an oxide layer (e.g., a pad oxide layer that may include silicon dioxide (SiO₂) or another material) and a nitride layer (e.g., a pad nitride layer that may include a silicon nitride such as SiₓN_{y} or another material) formed over the oxide layer. The spacer layers 220 include a silicon oxycarbide (SiOC), a nitrogen free SiOC, or another suitable material. The gate dielectric layer 225 may include a silicon oxide (e.g., SiOₓ such as SiO₂), a silicon nitride (e.g., SiₓN_{y} such as Si₃N₄), a high dielectric constant (high-k) dielectric material (e.g., a dielectric material having a dielectric constant greater than approximately 3.9) and/or another suitable material.

The layers of the dummy gate structures 205 may be formed using various semiconductor processing techniques such as depositing the layers of the dummy gate structures 205, patterning the layers of the dummy gate structures 205 to define the dummy gate structures 205, and/or other semiconductor processing techniques.

FIG. 2 further illustrates reference cross-sections that are used in subsequent figures described herein. Cross-section A-A is in a y-z plane (referred to as ay-cut) across the fin structures 150 in the source/drain areas of the semiconductor device 105. Cross-section B-B is in an x-z plane (referred to as an x-cut) perpendicular to the cross-section A-A, and is across the dummy gate structures 205 and along an underlying fin structure 150. Cross-section C-C is in the x-z plane parallel to the cross-section A-A and perpendicular to the cross-section B-B, and is along a dummy gate structure 205. Subsequent figures refer to these reference cross-sections for clarity. In some figures, some reference numbers of components or features illustrated therein may be omitted to avoid obscuring other components or features for ease of depicting the figures.

As indicated above, FIG. 2 is provided as an example. Other examples may differ from what is described with regard to FIG. 2.

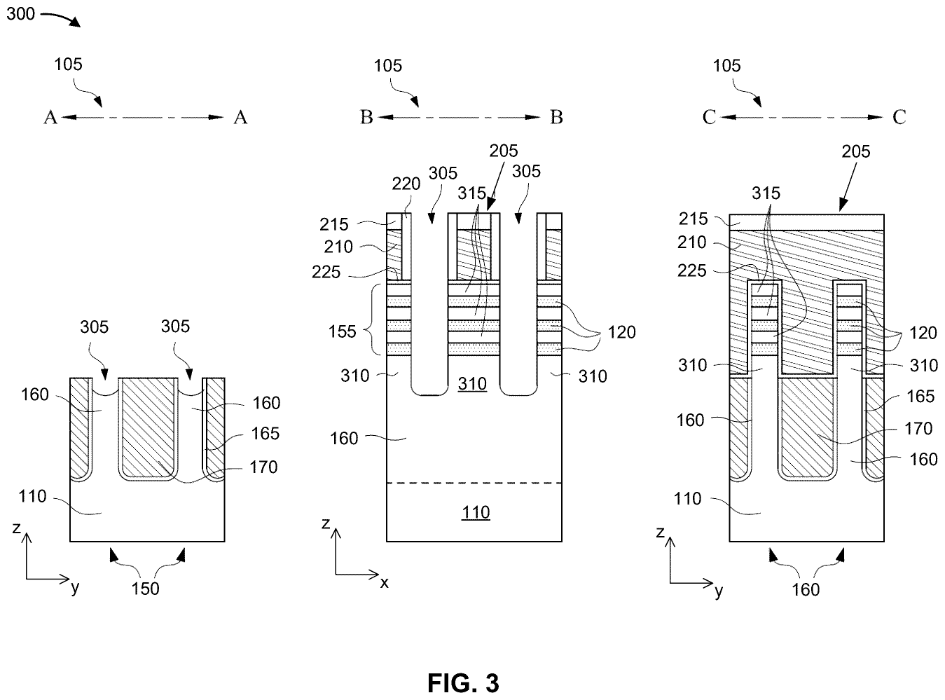

FIG. 3 is a diagrams of an example implementation 300 of a source/drain recess formation process described herein. The example implementation 300 includes an example of forming source/drain recesses 305 for source/drain regions of nanostructure transistors of the semiconductor device 105. FIG. 3 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 300 are performed after the processes described in connection with FIGS. 1A-2.

As shown in the cross-sectional plane A-A and cross-sectional plane B-B in FIG. 3, the source/drain recesses 305 are formed through portions 155 of a fin structure 150 in an etch operation. The source/drain recesses 305 are formed on opposing sides of a dummy gate structure 205. The etch operation may be performed using the etch tool and may be referred to a strained source/drain (SSD) etch operation. In some implementations, the etch operation includes the use of a plasma etch technique, a wet chemical etch technique, and/or another type of etch technique.

The source/drain recesses 305 also extend into a portion of the fin portion 160 of the fin structure 150. This results in formation of mesa regions 310 in the fin structure 150. The sidewalls of the portions of each source/drain recess 305 below the layer stack 115 correspond to sidewalls of mesa regions 310. A mesa region 310 (also referred to as pedestals) refers to a region of the fin portion 160 of the fin structure 150 on which nanostructure channels are defined from the nanostructure channel layers 125. The nanostructure channels 315 extend between adjacent source/drain recesses 305 and are located under the dummy gate structure 205 between the adjacent source/drain recesses 305.

The nanostructure channels 315 include silicon-based nanostructures (e.g., nanosheets or nanowires, among other examples) that function as the semiconductive channels of the nanostructure transistors of the semiconductor device 105. In some implementations, the nanostructure channels 315 may include silicon germanium (SiGe) or another silicon-based material. The nanostructure channels 315 are arranged in a direction (e.g., the z-direction) that is approximately perpendicular to the semiconductor substrate 110. In other words, the nanostructure channels 315 are vertically arranged or stacked above the semiconductor substrate 110.

As indicated above, FIG. 3 is provided as an example. Other examples may differ from what is described with regard to FIG. 3.

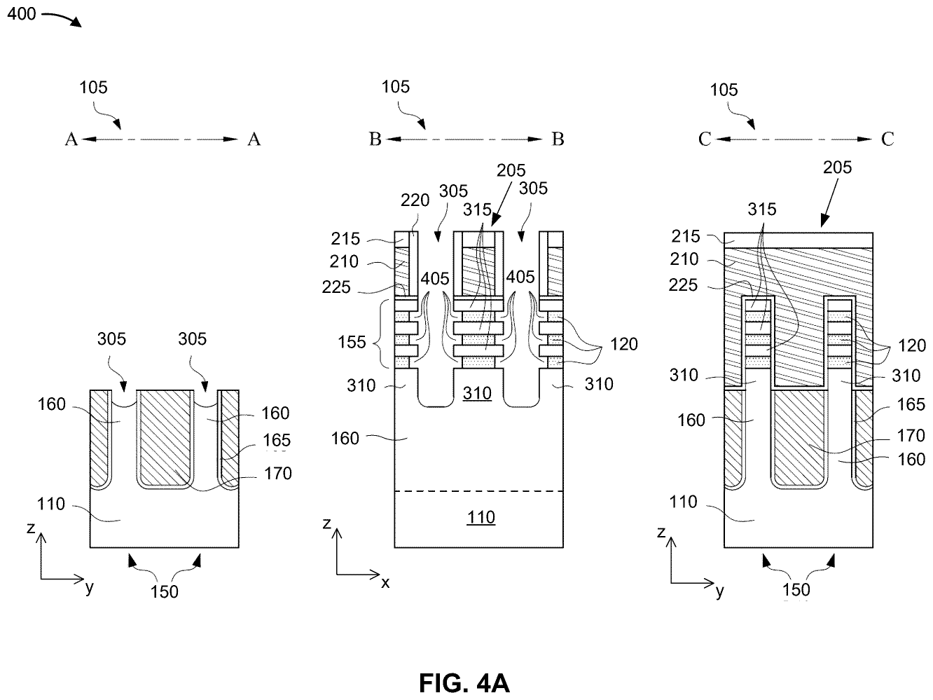

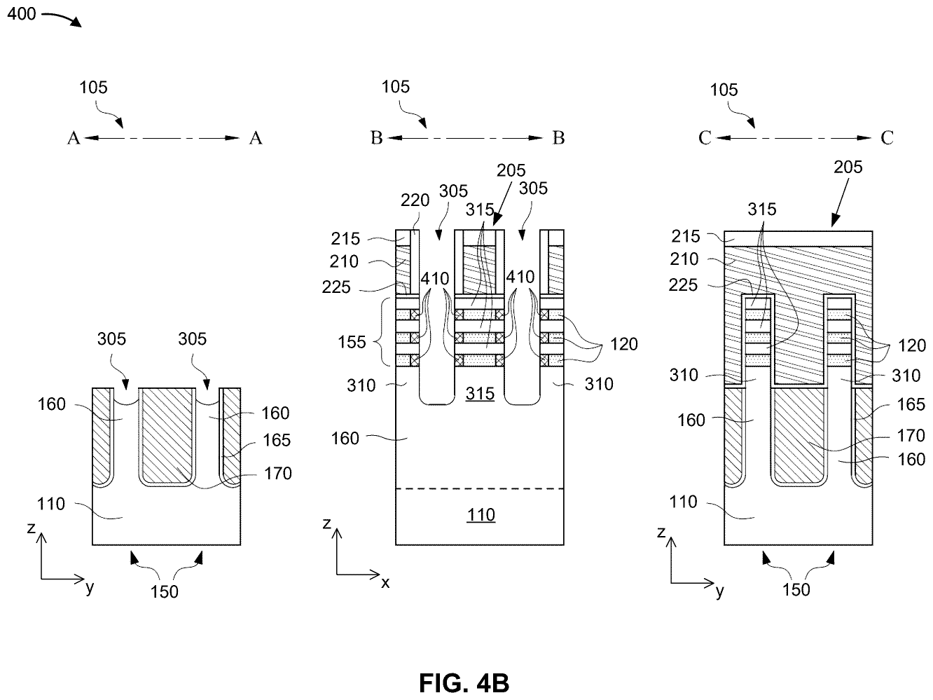

FIGS. 4A and 4B are diagrams of an example implementation 400 of a dummy inner spacer formation process described herein. The example implementation 400 includes an example of forming dummy inner spacers between ends of the nanostructure channels 315 that are exposed in the source/drain recesses 305. The dummy inner spacers are formed to enable buffer regions to be formed at the bottom of the source/drain recesses 305 prior to formation of inner spacers (replacement inner spacers) between ends of the nanostructure channels 315 that are exposed in the source/drain recesses 305. FIGS. 4A and 4B are each illustrated from a plurality of perspectives illustrated in FIG. 2, including the perspective of the cross-sectional plane A-A in FIG. 2, the perspective of the cross-sectional plane B-B in FIG. 2, and/or the perspective of the cross-sectional plane C-C in FIG. 2. In some implementations, the operations described in connection with the example implementation 400 are performed after the processes described in connection with FIGS. 1A-3.

As shown in the cross-sectional plane B-B in FIG. 4A, the ends of the sacrificial nanostructure layers 120 that are exposed in the source/drain recesses 305 are laterally etched (e.g., in the y-direction that is approximately parallel to a length of the sacrificial nanostructure layers 120) in an etch operation, thereby forming cavities 405 between the ends of the nanostructure channels 315 that are exposed in the source/drain recesses 305. In particular, an etch tool may be used to laterally etch the ends of the sacrificial nanostructure layers 120 under the dummy gate structures 205 through the source/drain recesses 305 to form the cavities 405 between ends of the nanostructure channels 315. The cavities 405 may be formed to an approximately curved shape, an approximately concave shape, an approximately triangular shape, an approximately square shape, or to another shape.

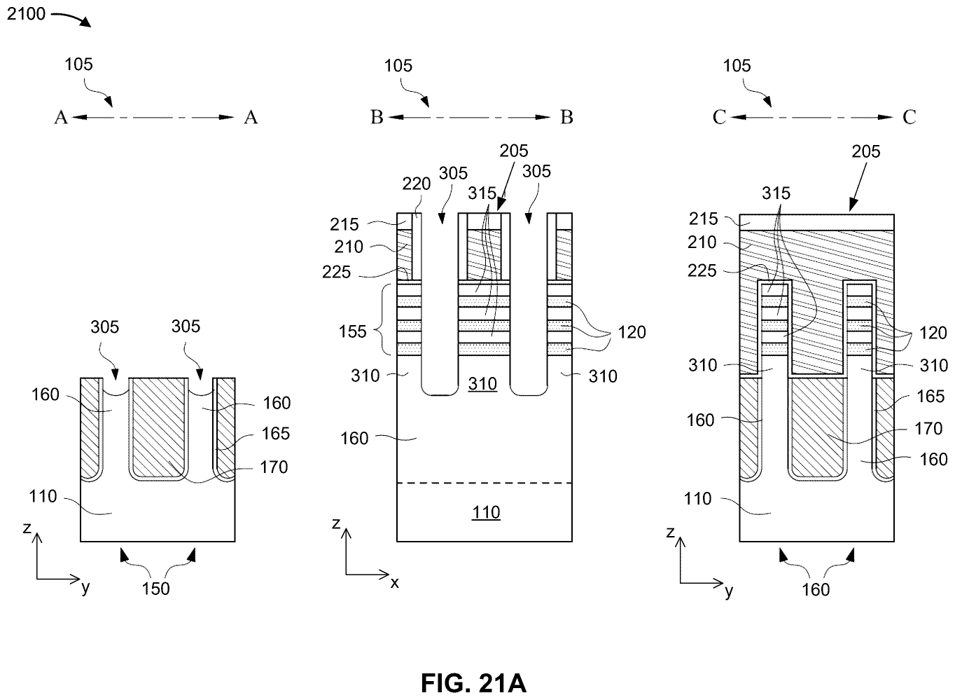

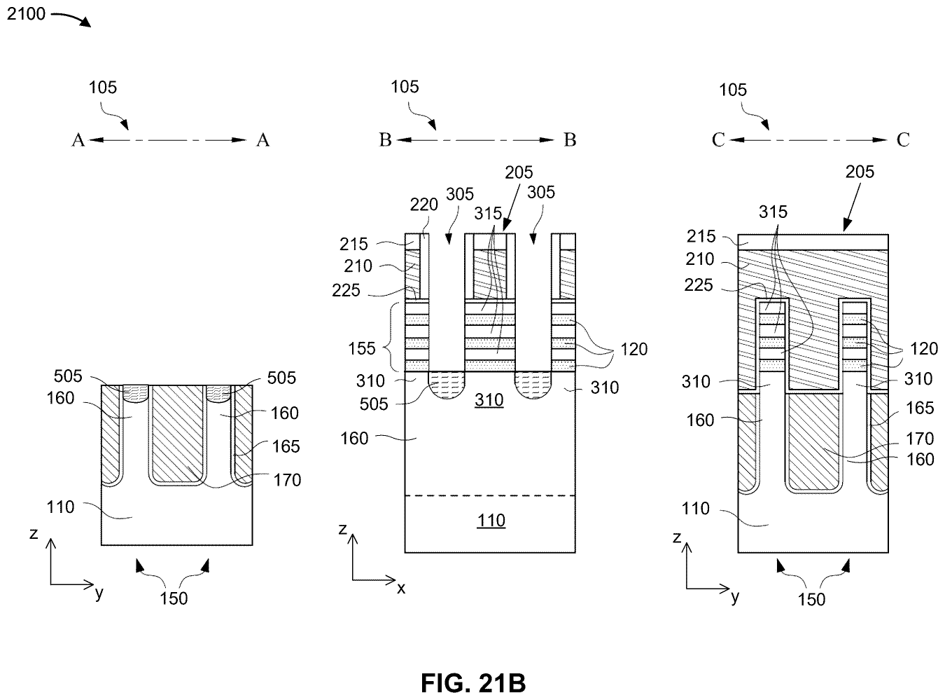

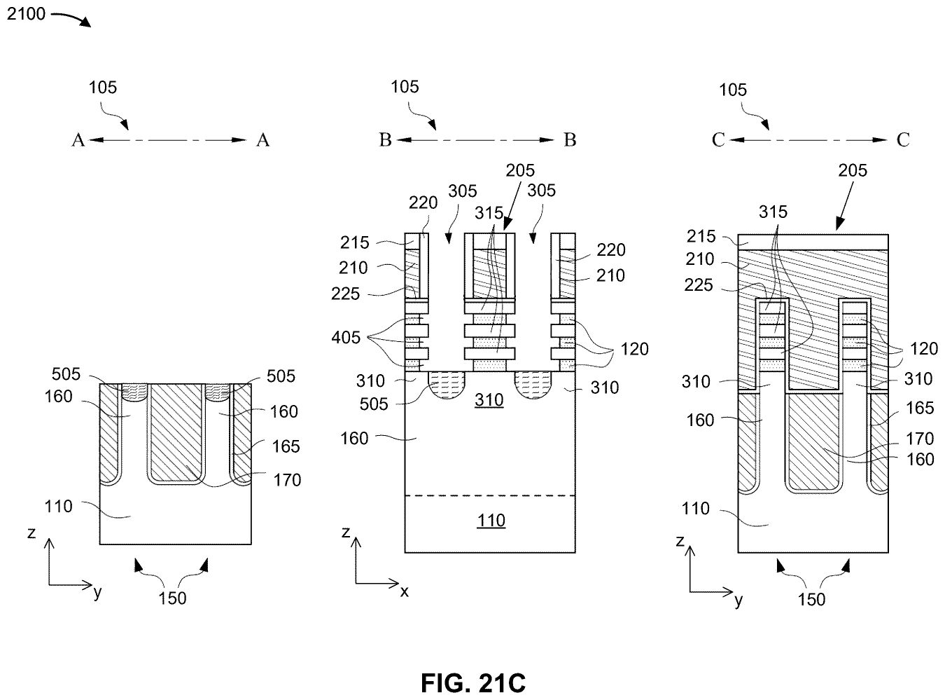

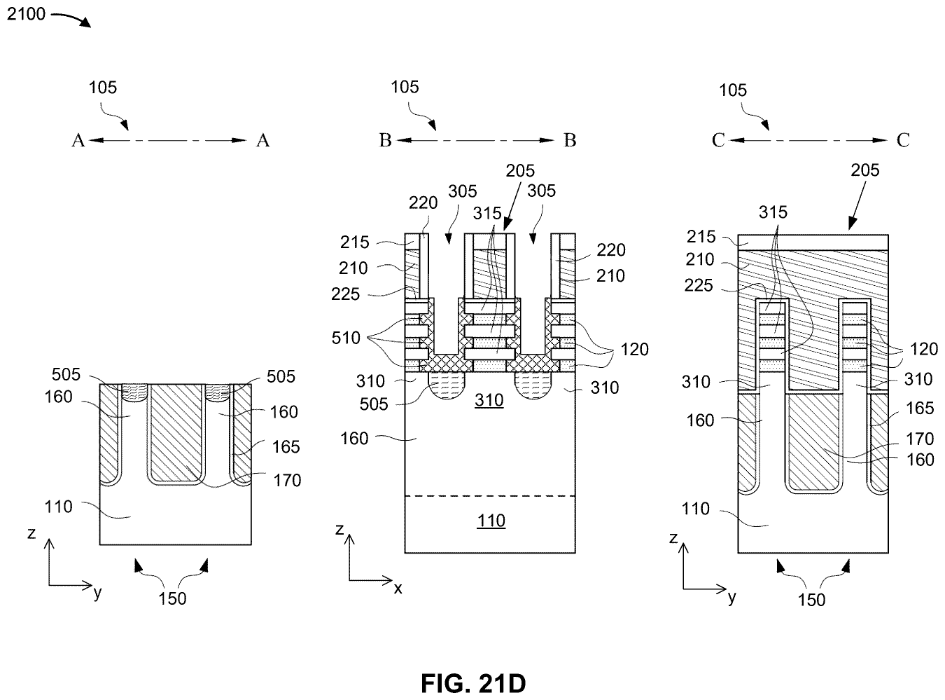

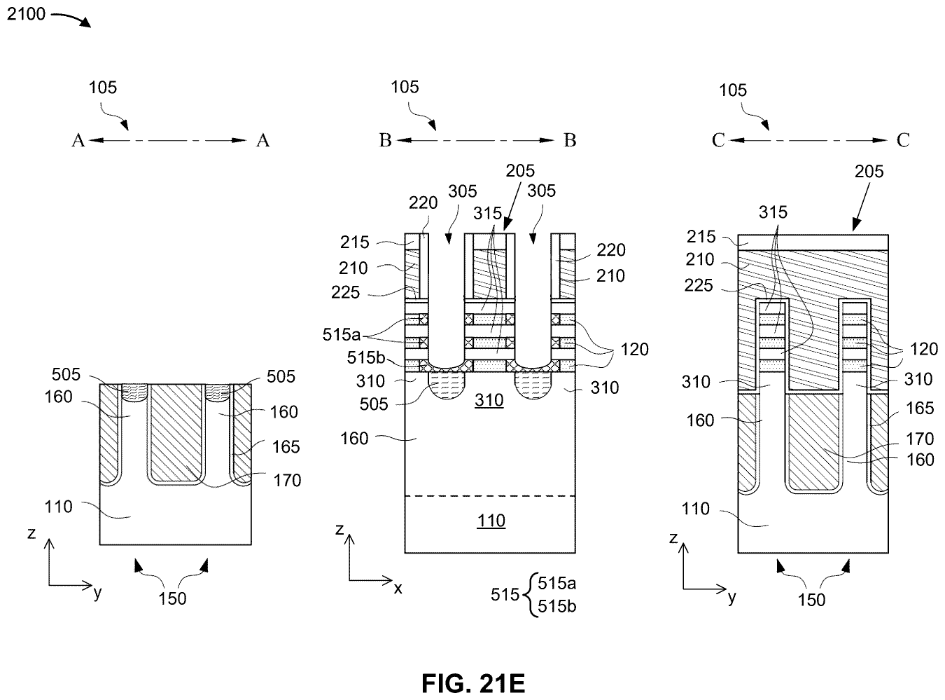

As shown in the cross-sectional plane B-B in FIG. 4B, dummy inner spacers 410 are formed in the cavities 405 between the ends of vertically adjacent nanostructure channels 315 in the source/drain recesses 305. The dummy inner spacer 410 are included to protect the cavities 405 during formation of buffer regions at the bottom of the source/drain recesses 305. FIGS. 21A-21E illustrate an alternative implementation in which dummy inner spacers 410 are omitted and inner spacers are instead formed directly in the cavities 405. In some implementations, the dummy inner spacers 410 include a silicon nitride (SiₓN_{y}), a silicon carbon nitride (SiCN), a silicon oxycarbonnitride (SiON), and/or another dielectric material. In some implementations, the dummy inner spacers 410 include an oxide material such as a silicon oxide (SiOₓ), a silicon oxynitride (SiON), and/or a silicon oxycarbide (SiOC), among other examples. In these implementations, the dummy inner spacers 410 may be referred to as a disposable oxide interposer (DOI).

To form the dummy inner spacers 410, a deposition tool may be used to deposit a layer of dielectric material in the cavities 405 and along the sidewalls and bottom surface of the source/drain recesses. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the dummy inner spacers 410 in the cavities 405. In some implementations, the etch operation may result in the surfaces of the dummy inner spacers 410 facing the source/drain recesses 305 being curved or recessed. In some implementations, the surfaces of the dummy inner spacers 410 facing the source/drain recesses 305 are approximately flat such that the surfaces of the dummy inner spacers 410 and the surfaces of the ends of the nanostructure channels 315 are approximately even and flush.

As indicated above, FIGS. 4A and 4B are provided as an example. Other examples may differ from what is described with regard to FIGS. 4A and 4B.

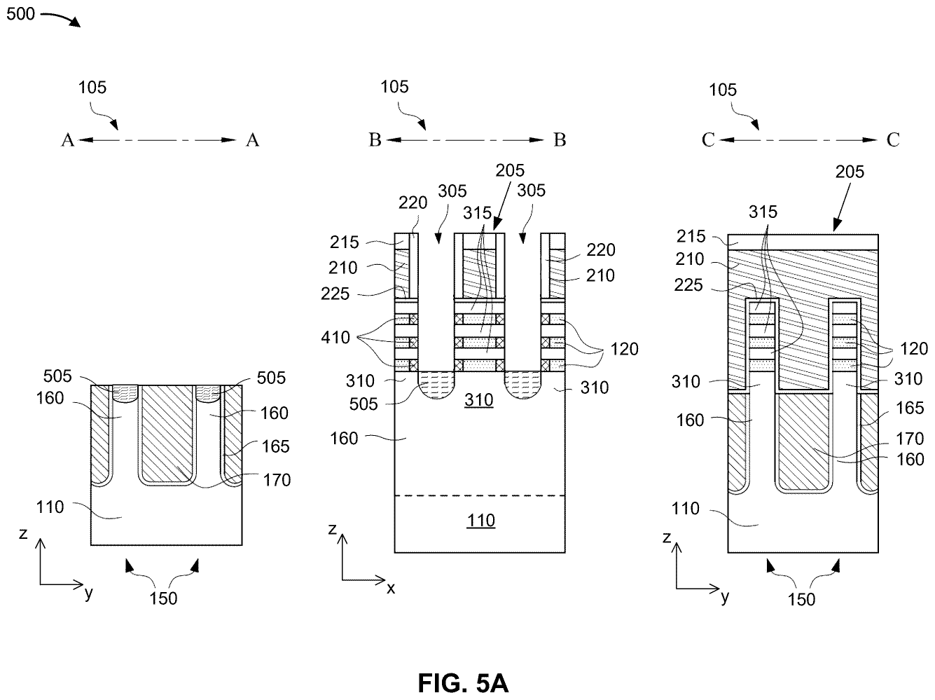

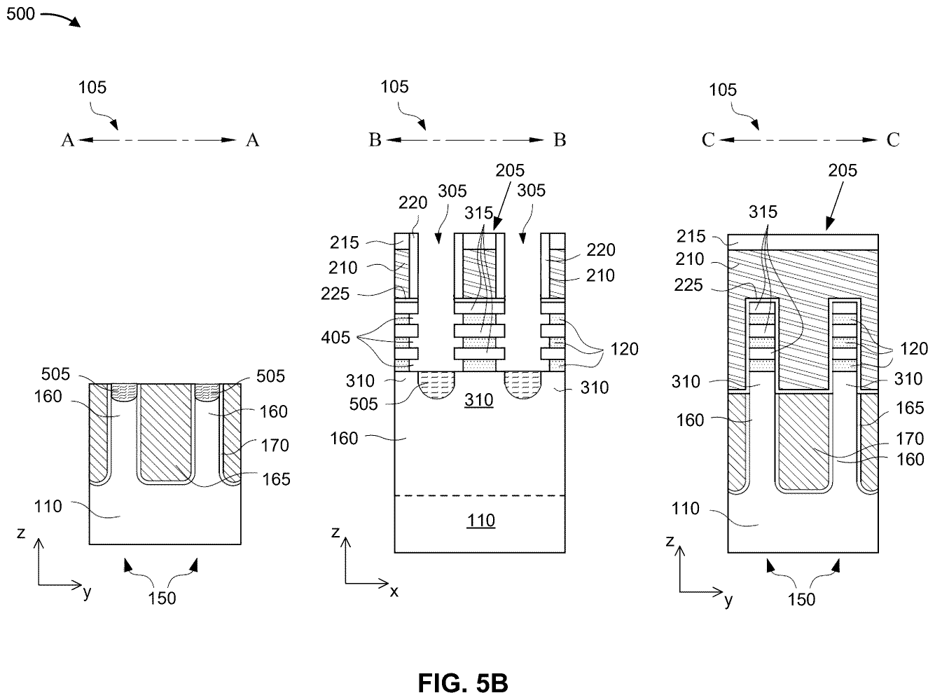

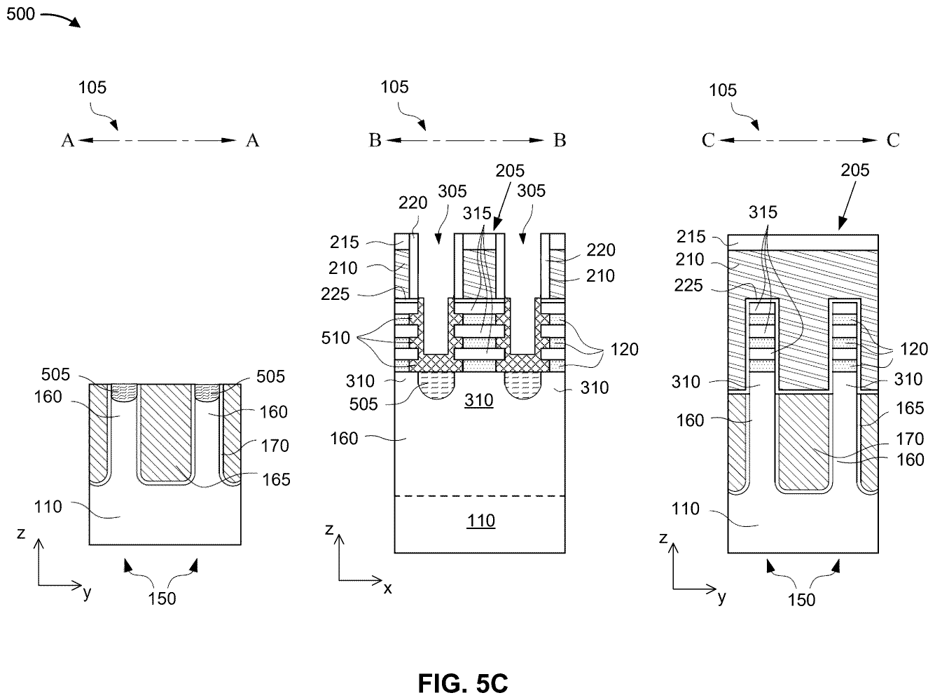

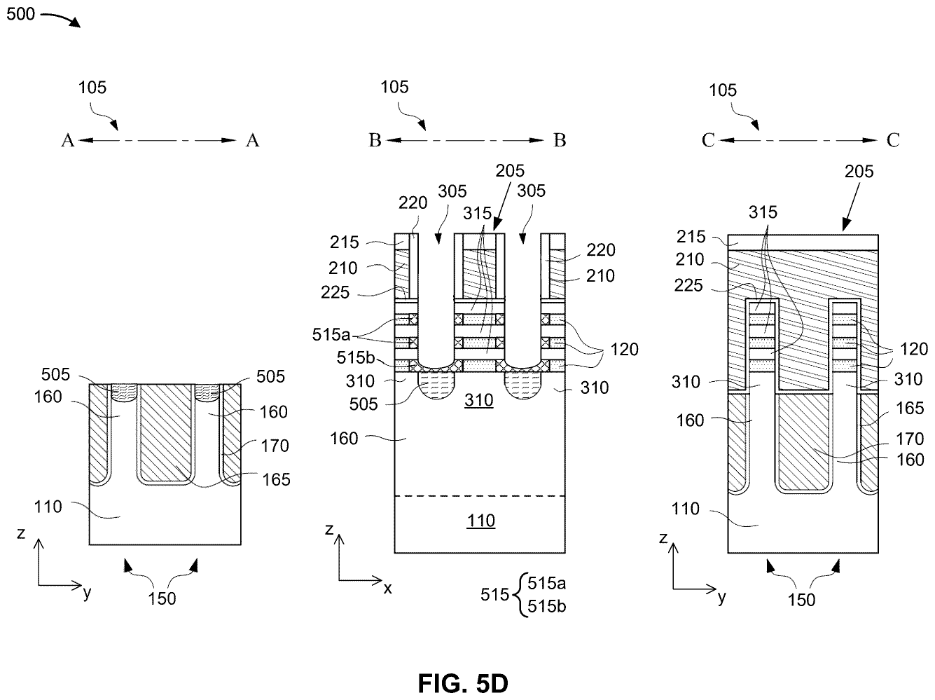

FIGS. 5A-5D are diagrams of an example implementation 500 of an inner spacer formation process described herein. The example implementation 500 includes an example of replacing the dummy inner spacers 410 with inner spacers. FIGS. 5A-5D are each illustrated from a plurality of perspectives illustrated in FIG. 2, including the perspective of the cross-sectional plane A-A in FIG. 2, the perspective of the cross-sectional plane B-B in FIG. 2, and/or the perspective of the cross-sectional plane C-C in FIG. 2. In some implementations, the operations described in connection with the example implementation 500 are performed after the processes described in connection with FIGS. 1A-4B.

As shown in the cross-sectional plane A-A and the cross-sectional plane B-B in FIG. 5A, a deposition tool may be used to deposit a buffer region 505 at the bottom of a source/drain recess 305. The dummy inner spacers 410 may protect the cavities 405 during formation of the buffer region 505. In particular, the dummy inner spacers 410 prevent material of the buffer region 505 from being deposited in the cavities 405.

A buffer region 505 may include silicon germanium (SiGe), undoped silicon (Si), silicon doped with boron (Si:B) or another dopant, and/or another material. In implementations in which the buffer region 505 includes silicon germanium, the germanium (Ge) concentration in the buffer region 505 may be in a range of approximately 1% germanium to approximately 10% germanium. However, other values for the germanium concentration are within the scope of the present disclosure.

A buffer region 505 may be included between a source/drain region and the mesa regions 310 adjacent to the buffer region 505 to reduce, minimize, and/or prevent dopant migration and/or current leakage from the source/drain region into the adjacent mesa region 310, which might otherwise cause short channel effects in the semiconductor device 105. Accordingly, the buffer region 505 may increase the performance of the semiconductor device 105 and/or increase yield of the semiconductor device 105.

As shown in FIG. 5A, a buffer region 505 may be formed such that the top surface of the buffer region 505 is substantially flat and approximately co-planar with the top surfaces of the adjacent mesa regions 310. In some implementations, a buffer region 505 is formed such that the top surface of the buffer region 505 is arc-shaped and recessed below the top surfaces of the adjacent mesa regions 310. In these implementations, the buffer region 505 has a concave top surface. In some implementations, a buffer region 505 is formed such that the top surface of the buffer region 505 is convex and extends above the top surfaces of the adjacent mesa regions 310.

As shown in the cross-sectional plane B-B in FIG. 5B, the dummy inner spacers 410 are laterally etched (e.g., in the y-direction that is approximately parallel to a length of the sacrificial nanostructure layers 120) and removed from the cavities 405 in an etch operation, thereby exposing the cavities 405 after formation of the buffer regions 505. In particular, an etch tool may be used to laterally etch the dummy inner spacers 410 through the source/drain recesses 305 to remove the dummy inner spacers 410.

As shown in the cross-sectional plane B-B in FIG. 5C, a deposition tool may be used to deposit an inner spacer layer 510 in the cavities 405 and along the sidewalls and bottom surface of the source/drain recesses 305. A CVD technique, a PVD technique, and ALD technique, an epitaxy technique, and/or another deposition technique may be used to deposit the layer of dielectric material.

As shown in the cross-sectional plane B-B in FIG. 5D, inner spacers 515 are formed in the cavities 405 between the ends of vertically adjacent nanostructure channels 315 in the source/drain recesses 305. The inner spacers 515 are included to protect source/drain regions (that are subsequently formed in the source/drain recesses 305) from being etched in a nanosheet release operation to remove the sacrificial nanostructure layers 120 between the nanostructure channels 315. An etch tool is used to remove excess material of the inner spacer layer 510 (e.g., may be used to trim the inner spacer layer 510 using a dry etch technique, a wet etch technique) from the source/drain recesses 305 such that remaining portions correspond to the inner spacers 515 in the cavities 405. In some implementations, the etch operation may result in the surfaces of the inner spacers 515 facing the source/drain recesses 305 being curved or recessed. In some implementations, the surfaces of the inner spacers 515 facing the source/drain recesses 305 are approximately flat such that the surfaces of the inner spacers 515 and the surfaces of the ends of the nanostructure channels 315 are approximately even and flush.

As further shown in FIG. 5D, the inner spacers 515 that are formed in a source/drain recess 305 may include inner spacers 515a (e.g., top inner spacers) that are formed in the cavities 405 above a bottom-most sacrificial nanostructure layer 120, and an inner spacer 515b that is formed in the cavities 405 in the bottom-most sacrificial nanostructure layer 120. The inner spacer 515b (e.g., a bottom inner spacer) may extend along the bottom surface of the source/drain recess 305, which corresponds to the top surface of the buffer region 505 in the source/drain recess 305. The portion of the inner spacer 515b between the cavities 405 in the bottom-most sacrificial nanostructure layer 120 may have a curved or arc-shaped top surface. In particular, the portion of the inner spacer 515b between the cavities 405 in the bottom-most sacrificial nanostructure layer 120 may have a recessed or concave top surface.

The inner spacers 515 may include a same material (or same material composition) as the sacrificial nanostructure layers 120. For example, the inner spacers 515 and the sacrificial nanostructure layers 120 may both include silicon germanium (SiGe). This enables the inner spacers 515 and the sacrificial nanostructure layers 120 to both be removed after formation of the source/drain regions and provides etch selectivity relative to the source/drain regions (which may be formed of different materials and/or different material compositions as the inner spacers 515 and the sacrificial nanostructure layers 120).

As indicated above, FIGS. 5A-5D are provided as an example. Other examples may differ from what is described with regard to FIGS. 5A-5D.

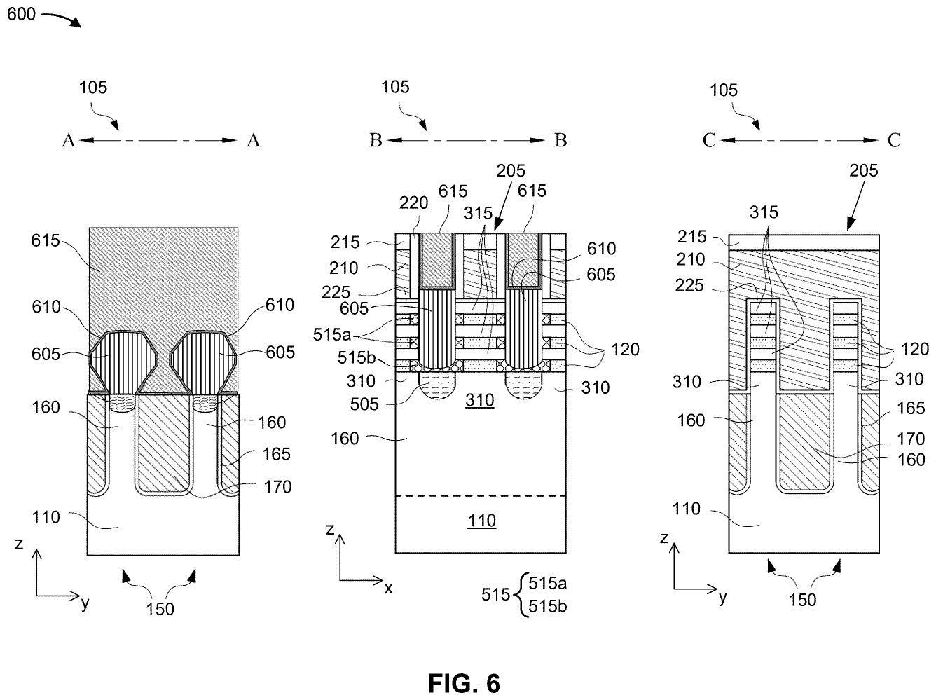

FIG. 6 is a diagram of an example implementation 600 of a source/drain region formation process and an interlayer dielectric (ILD) formation process described herein. The example implementation 600 includes an example of forming the source/drain regions of the nanostructure transistors of the semiconductor device 105, and forming an ILD layer on the source/drain regions. FIG. 6 is illustrated from a plurality of perspectives illustrated in FIG. 2, including the perspective of the cross-sectional plane A-A in FIG. 2, the perspective of the cross-sectional plane B-B in FIG. 2, and/or the perspective of the cross-sectional plane C-C in FIG. 2. In some implementations, the operations described in connection with the example implementation 600 are performed after the processes described in connection with FIGS. 1A-5D.

As shown in FIG. 6, source/drain regions 605 may be formed above the buffer regions 505 in the source/drain recesses 305. A source/drain region 605 may refer to a source or a drain, individually or collectively dependent upon the context. Source/drain regions 605 may be included on opposing sides of a dummy gate structure 205 such that the nanostructure channels 315 under the dummy gate structure 205 extend between, and are electrically coupled with, source/drain regions 605. The source/drain regions 605 may have bottom surfaces that have a curved cross-sectional profile. The source/drain regions 605 each include silicon (Si) and/or silicon germanium (SiGe) with one or more dopants, such as a p-type material (e.g., boron (B) or gallium (Ga), among other examples), an n-type material (e.g., phosphorous (P) or arsenic (As), among other examples), and/or another type of dopant. Accordingly, the semiconductor device 105 may include p-type metal-oxide semiconductor (PMOS) nanostructure transistors that include p-type source/drain regions 605, n-type metal-oxide semiconductor (NMOS) nanostructure transistors that include n-type source/drain regions 605, and/or other types of nanostructure transistors. In some implementations, a dopant concentration in a source/drain region may be included in a range of approximately 1×10¹⁷ ions per cubic centimeter (ions/cm³) to approximately 5×10²² ions/cm³. However, other values for the range are within the scope of the present disclosure.

In some implementations, sidewalls of a source/drain region 605 may be in physical contact with inner spacers 515a, and a bottom surface of the source/drain region 605 may be in physical contact with an inner spacer 515b. In some implementations, a plurality of inner spacers 515b (e.g., a plurality of bottom-most inner spacer 515) are formed such that the top surface of the associated buffer region 505 is exposed in the source/drain recess 305 (e.g., such that the top surface of the buffer region 505 is not covered by the inner spacers 515b). In these implementations, a source/drain region 605 may be formed in the source/drain recess 305 such that the bottom surface of the source/drain region is in physical contact with the top surface of the buffer region 505, and the inner spacers 515b are in physical contact with the sidewalls of the source/drain region 605 in a similar manner as the inner spacers 515a.

One or more layers of a source/drain region 605 may be epitaxially grown, deposited (e.g., using CVD, PVD, ALD), and/or may be formed using one or more other deposition techniques. For example, a deposition tool may epitaxially grow a first layer of a source/drain region 605 (referred to as an L1) over an associated buffer region 505 (which may be referred to as an L0), and may epitaxially grow a second layer of the source/drain region 605 (referred to as an L2, an L2-1, and/or an L2-2) over the first layer. The first layer may include a lightly doped silicon (e.g., doped with boron (B), phosphorous (P), and/or another dopant), and may be included as shielding layer to reduce short channel effects in the semiconductor device 105 and to reduce dopant extrusion or migration into the nanostructure channels 315. The second layer may include a highly doped silicon or highly doped silicon germanium. The second layer may be included to provide a compressive stress in the source/drain regions 605 to reduce boron or phosphorous loss.

As further shown in FIG. 6, a contact etch stop layer (CESL) 610 is conformally deposited (e.g., by a deposition tool) over the source/drain regions 605. A dielectric layer 615 is then formed on the CESL 610 above the source/drain regions 605. The CESL 610 may provide a mechanism to stop an etch process when forming contacts or vias for the source/drain regions 605. The CESL may be formed of a dielectric material having a different etch selectivity from adjacent layers or components. The CESL 610 may include or may be a nitrogen containing material, a silicon containing material, and/or a carbon containing material. Furthermore, the CESL 610 may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL 610 may be deposited using a deposition process, such as ALD, CVD, or another deposition technique.

The dielectric layer 615 fills in areas between the dummy gate structures 205. The dielectric layer 615 is formed to reduce the likelihood of and/or prevent damage to the source/drain regions 605 during a replacement gate process to replace the dummy gate structures 205. The dielectric layer 615 may be referred to as an ILD zero (ILD0) layer or another ILD layer.

As indicated above, FIG. 6 is provided as an example. Other examples may differ from what is described with regard to FIG. 6.

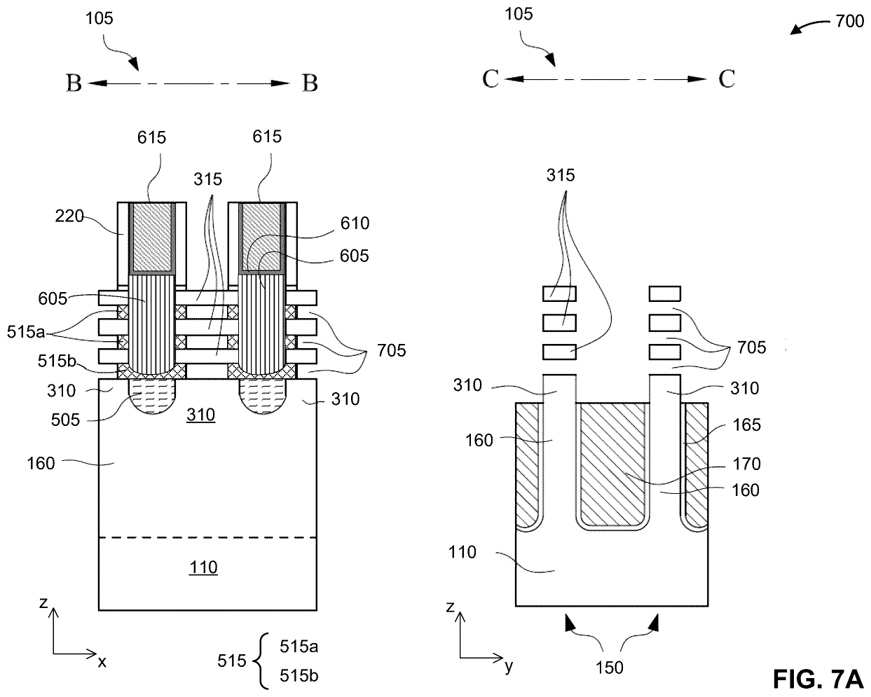

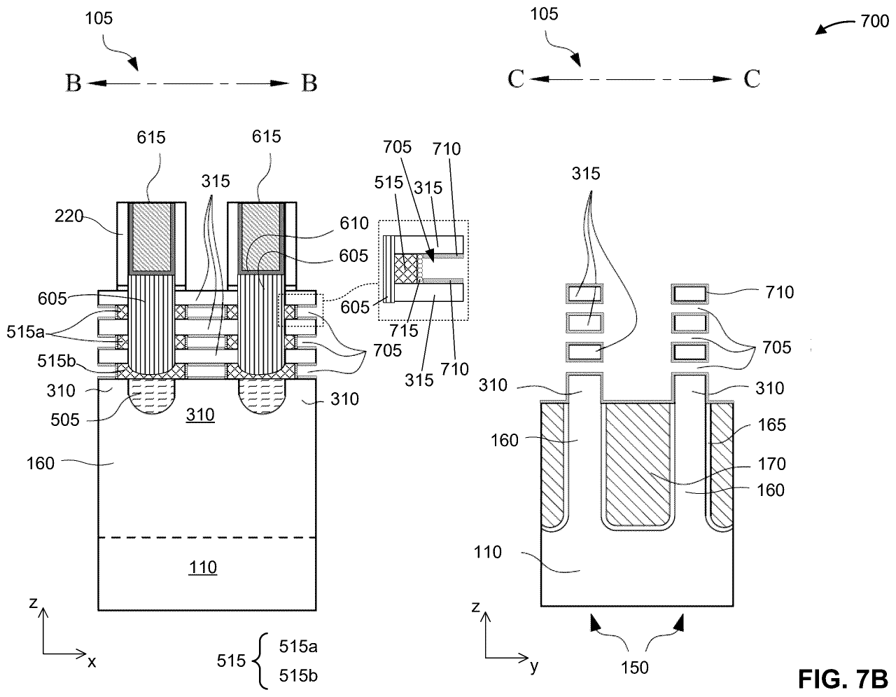

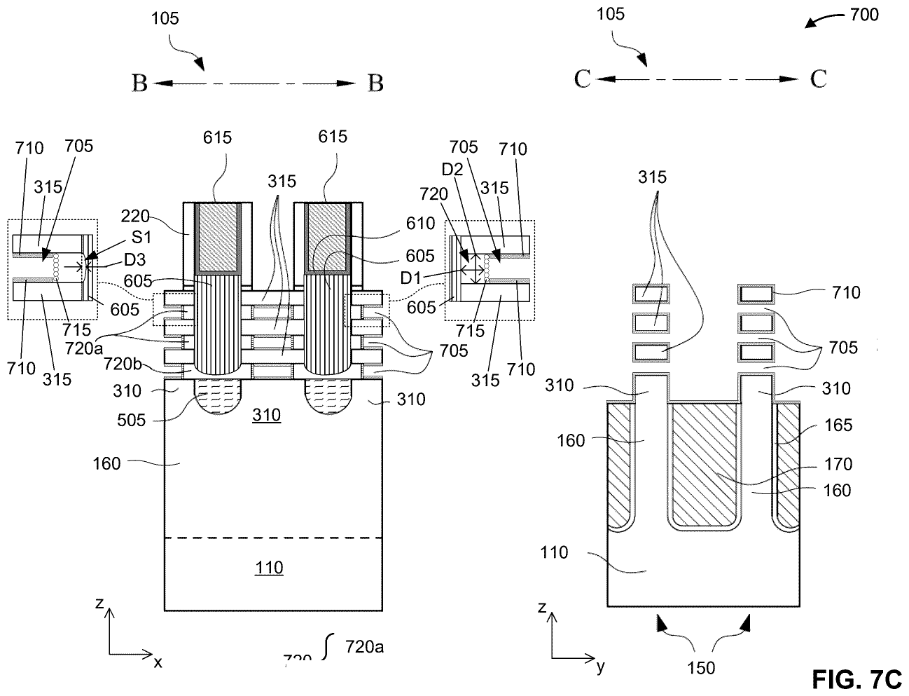

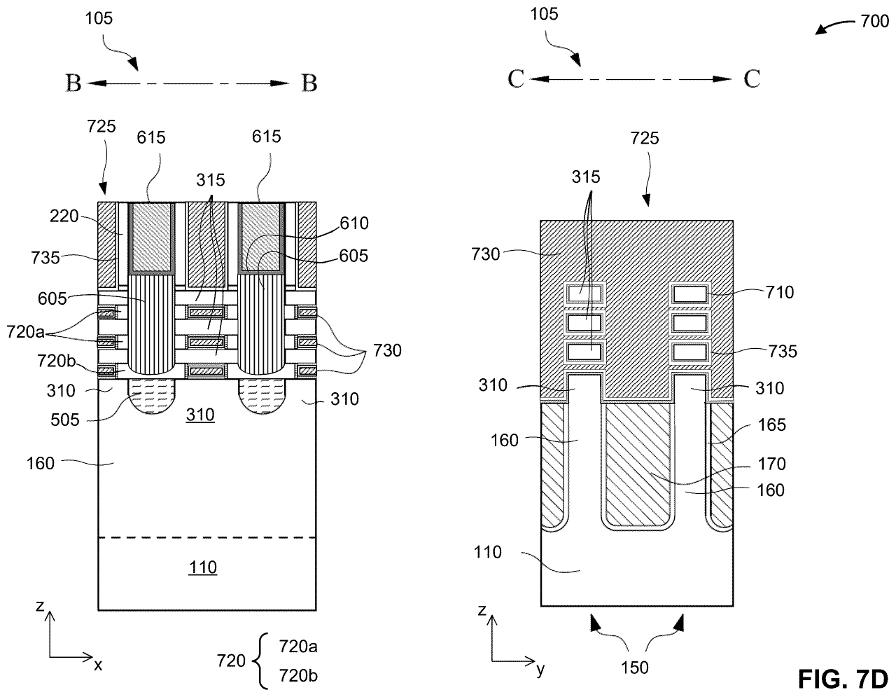

FIGS. 7A-7D are diagrams of an example implementation 700 of a replacement gate (RPG) process described herein. The example implementation 700 includes an example of a replacement gate process for replacing the dummy gate structures 205 with high-k/metal gate structures (e.g., the replacement gate structures) for the nanostructure transistors of the semiconductor device 105. FIGS. 7A-7D are each illustrated from a plurality of perspectives illustrated in FIG. 2, including the perspective of the cross-sectional plane A-A in FIG. 2, the perspective of the cross-sectional plane B-B in FIG. 2, and/or the perspective of the cross-sectional plane C-C in FIG. 2. In some implementations, the operations described in connection with the example implementation 700 are performed after the operations described in connection with FIGS. 1A-6.

As shown in the cross-sectional plane B-B and the cross-sectional plane C-C in FIG. 7A, the replacement gate process includes a dummy gate removal operation. The dummy gate removal operation includes removing the dummy gate structures 205 from the semiconductor device 105. The removal of the dummy gate structures 205 leaves behind openings (or recesses) between the dielectric layer 615, and provides access to the underlying sacrificial nanostructure layers 120. The dummy gate structures 205 may be removed in one or more etch operations. Such etch operations may include a plasma etch technique, a wet chemical etch technique, and/or another type of etch technique.

As further shown FIG. 7A, the replacement gate process includes a nanostructure release operation (e.g., an SiGe release operation). The nanostructure release operation is performed to remove the sacrificial nanostructure layers 120 (e.g., the silicon germanium layers). This results in openings 705 between the nanostructures channels 315 (e.g., the areas around the nanostructure channels 315). The inner spacers 515a and 515b are exposed through the openings 705. The sacrificial nanostructure layers 120 may be removed through the spaces that were previously occupied by the dummy gate structures 205. The nanostructure release operation may include the use of an etch tool to perform an etch operation to remove the sacrificial nanostructure layers 120 based on a difference in etch selectivity between the material of the sacrificial nanostructure layers 120 and the material of the nanostructure channels 315. The inner spacers 515a and 515b may function as etch stop layers in the etch operation to protect the source/drain regions 605 from being etched.

As shown in the cross-sectional plan B-B and the cross-sectional plane C-C in FIG. 7B, interfacial layers 710 may be formed on the surfaces of the nanostructure channels 315 that are exposed in the openings 705. The interfacial layers 710 may include an oxide layer such as a silicon oxide (SiOₓ such as SiO₂), among other examples. As further shown in FIG. 7B, porous interfacial layers 715 may be formed on ends of the inner spacers 515a and 515b that are exposed through the openings 705. The porous interfacial layers 715 may include the same oxide material as the interfacial layer 710, except that pores (or openings or holes) are formed through the porous interfacial layers 715. This enables an etchant to be provided to the inner spacers 515a and 515b through the pores in the porous interfacial layers 715 so that the inner spacers 515a and 515b can be removed through the pores in the porous interfacial layers 715.

Forming the interfacial layers 710 may include oxidizing the exposed surfaces of the nanostructure channels 315 by providing an oxidizer through the openings 705. The oxidizer may include an acid, ammonia (NH₃), hydrogen peroxide (H₂O₂), and/or another suitable oxidizer. The oxidizer reacts with the exposed surfaces of the nanostructure channels 315 to form an oxide of the material of the nanostructure channels 315.

Similarly, forming the porous interfacial layers 715 on the ends of the inner spacers 515a and 515b may include oxidizing the ends of the inner spacers 515a and 515b to form an oxide layer on the ends of the inner spacers 515a and 515b. Additionally, to form the pores in the oxide layer, an electrochemical etch of the oxide layer may be performed to remove material from the oxide layer to form the porous interfacial layers 715.

In some implementations, a thickness of a porous interfacial layer 715 is greater than 0 nanometers and less than or approximately equal to 1 nanometer. If the porous interfacial layer 715 is not sufficiently thick, the porous interfacial layer 715 may destruct and fail, resulting in formation of a high-K dielectric liner directly on the adjacent source/drain region 605 (resulting in gate to source/drain shorting). If the porous interfacial layer 715 is too thick, insufficient space in the openings 705 may be available for forming a gate structure in the openings 705, resulting in increased gate resistance. If the thickness of the porous interfacial layer 715 is greater than 0 nanometers and less than or approximately equal to 1 nanometer, a sufficiently low gate resistance may be achieved while reducing the likelihood of gate to source/drain shorting. However, other values for the range are within the scope of the present disclosure.

As shown in the cross-sectional plan B-B in FIG. 7C, the inner spacers 515a and 515b are removed from the semiconductor device 105 through the openings 705. In particular, the inner spacers 515a and 515b are removed through the openings 705 by removing the material of the inner spacers 515a and 515b through the pores in the porous interfacial layers 715. The pores in the porous interfacial layers 715 enable an etchant to be provided to the inner spacers 515a and 515b through the pores in the porous interfacial layers 715 such that the etchant can be used to remove material from the inner spacers 515a and 515b through the pores in the porous interfacial layers 715.

Removing the inner spacers 515a results in the formation of air gaps 720a in the spaces previously occupied by the inner spacers 515a. For example, the air gaps 720a may be included between the sidewall of a source/drain region 605 and the porous interfacial layers 715 that were formed on the inner spacers 515a.

Similarly, removing an inner spacer 515b results in the formation of an air gap 720b in the space previously occupied by the inner spacer 515b. For example, the air gap 720b may be included between the bottom surface of a source/drain region 605 and a buffer region 505 under the bottom surface of the source/drain region 605. In some implementations, a single air gap 720b spans across the entire bottom surface of the source/drain region 605 and around the ends of the associated nanostructure channels 315. In some implementations, the bottom surface of the source/drain region 605 is in contact with the underlying buffer region 505, and air gaps 720b are included on opposing sides of the source/drain region 605 similar to the air gaps 720a.

The thickness of the air gap 720b (corresponding to a distance between the bottom surface of the source/drain region 605 and the top surface of the buffer region 505) may be included in a range of approximately 0.5 nanometers to approximately 10 nanometers to enable a low parasitic capacitance to be achieved between the buffer regions 505 and the gate structures that are to be formed in the semiconductor device 105. However, other values for the range are within the scope of the present disclosure. In some implementations, the air gap 720b protrudes into the bottom surface of the source/drain region 605. In some implementations, the air gap 720b protrudes into the top surface of the buffer region 505. Alternatively, if the bottom surface of the source/drain region 605 and the top surface of the buffer region 505 are substantially flat, the air gap 720b is approximately rectangular in shape.

In some implementations, over etching may occur when removing the inner spacers 515a and 515b. In these implementations, the air gaps 720a and/or 720b may protrude into the adjacent source/drain region 605, resulting in scalloped sidewalls S1 for the source/drain region 605. In some implementations, the depth D3 of the scallops S1 in the sidewalls may be included in a range of approximately 1 nanometer to approximately 10 nanometers. However, other values for the range are within the scope of the present disclosure. In some implementations, an air gap 720b protrudes into a bottom surface of a source/drain region 605 if over etching occurs in the bottom surface of the source/drain region 605 when removing an associated inner spacer 515b.

As further shown in FIG. 7C, an air gap 720 (e.g., an air gap 720a, an air gap 720b) may have one or more dimensions, such as a horizontal width (e.g., an x-direction width) indicated in FIG. 7C as dimension D1 and/or a vertical height (e.g., a z-direction height) indicated in FIG. 7C as dimension D2. In some implementations, the dimension D1 and the dimension D2 are each included in a range of approximately 1 nanometer to approximately 15 nanometers to enable a sufficiently low parasitic capacitance to be achieved between an associated source/drain region 605 and a gate structure that is to be formed in the openings 705. However, other values for the range are within the scope of the present disclosure.

As shown in the cross-sectional plan B-B and the cross-sectional plane C-C in FIG. 7D, the replacement gate operation includes forming gate structures (e.g., replacement gate structures) 725 in the openings 705 between the source/drain regions 605. In particular, the gate structures 725 fill the areas between and around the nanostructure channels 315 that were previously occupied by the sacrificial nanostructure layers 120 such that the gate structures 725 fully wrap around the nanostructure channels 315 and surround the nanostructure channels 315. This increases control of the nanostructure channel 315, increases drive current for the nanostructure transistor(s) of the semiconductor device 105, and/or reduces short channel effects (SCEs) for the nanostructure transistor(s) of the semiconductor device 105, among other examples. The gate structures 725 may also fill in the spaces that were previously occupied by the dummy gate structures 205. Portions of a gate structure 725 are formed in between pairs of nanostructure channels 315 in an alternating vertical arrangement. In other words, the semiconductor device 105 includes one or more vertical stacks of alternating nanostructure channels 315 and portions of a gate structure 725, as shown in FIG. 7D.

As further shown in FIG. 7D, the air gaps 720a and 720b are located between a gate structure 725 and the source/drain regions 605 located on opposing sides of the gate structure 725. The gate structures 725 may include a metal gate electrode 730 and a high-k dielectric liner 735. The metal gate electrode 730 may include one or more metal materials such as tungsten (W), cobalt (Co), ruthenium (Ru), and/or titanium (Ti), among other examples. Additionally and/or alternatively, the gate structure 725 may include one or more work function metal layers for tuning the work function of the metal gate electrode 730.

The high-k dielectric liners 735 are conformally deposited on the interfacial layers 710 around the nanostructure channels 315, and the metal gate electrode 730 is formed on the high-k dielectric liners 735. The porous interfacial layers 715 prevent, minimize, and/or reduce the likelihood of material of the high-k dielectric liners 735 being deposited into the air gaps 720a and 720b. The high-k dielectric liners 735 each include one or more high-k dielectric materials, such as a silicon nitride (SiₓN_{y}), a hafnium oxide (HfOₓ), a lanthanum oxide (LaOₓ), and/or another suitable high-k dielectric material.

As indicated above, FIGS. 7A-7D are provided as an example. Other examples may differ from what is described with regard to FIGS. 7A-7D.

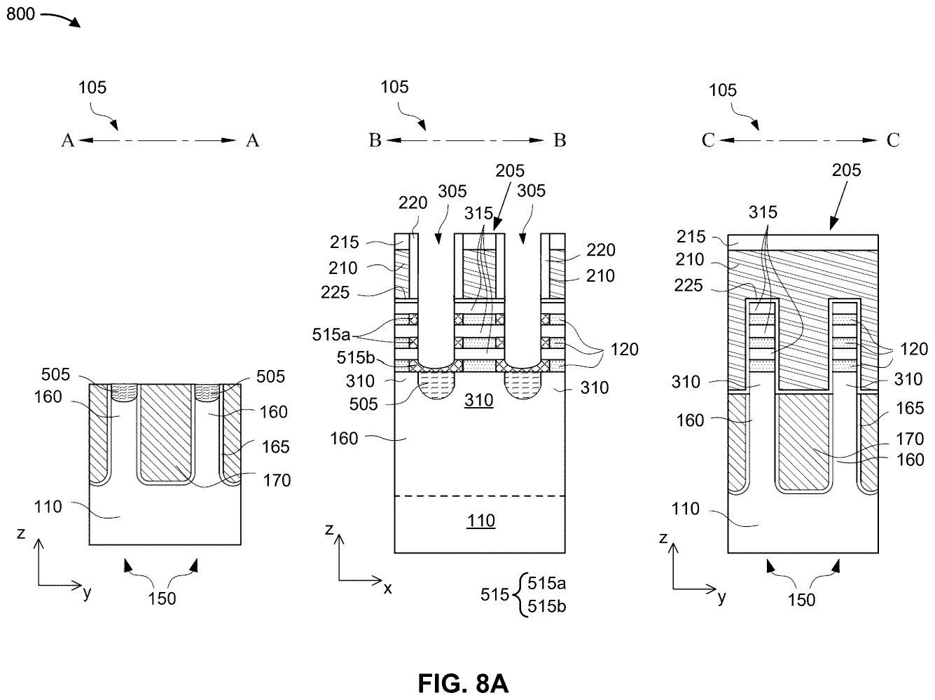

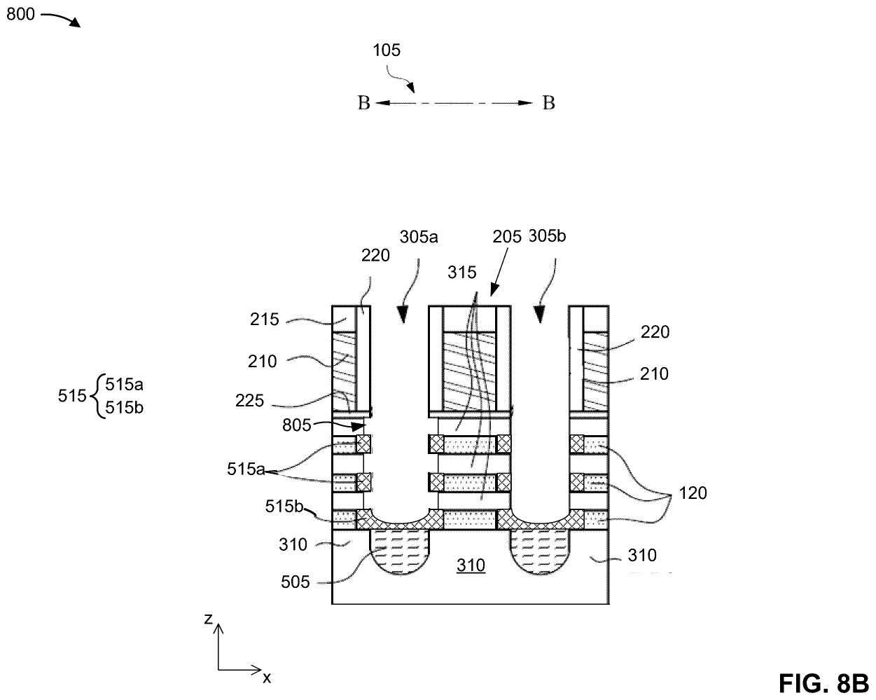

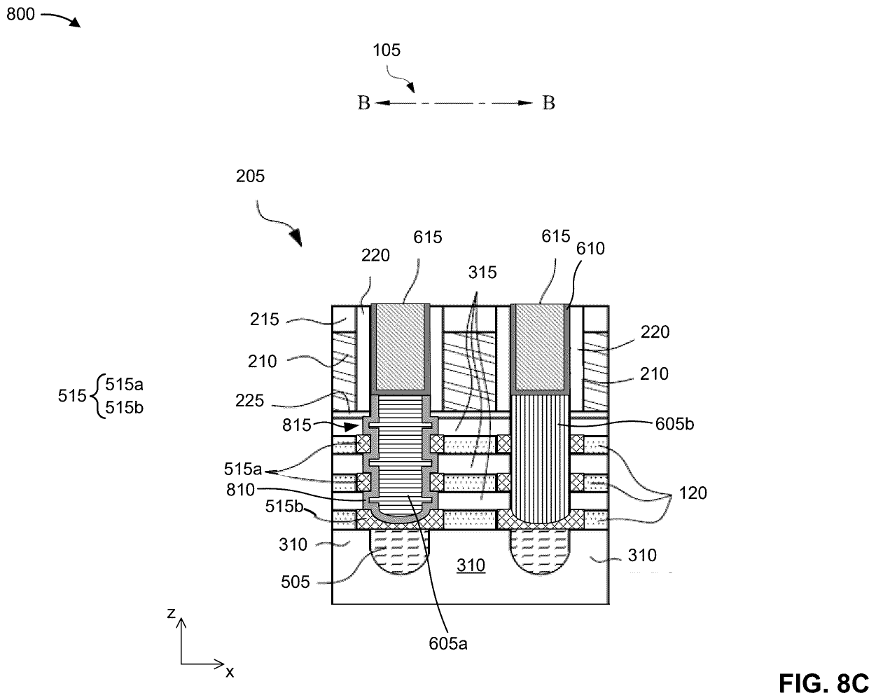

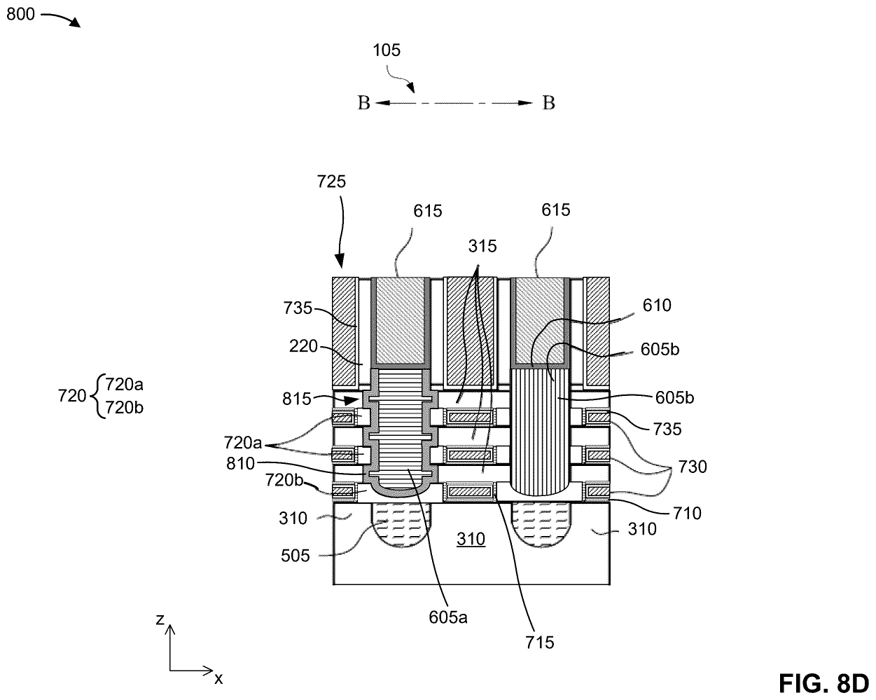

FIGS. 8A-8D are diagrams of an example implementation 800 forming the semiconductor device 105 described herein. The example implementation 800 includes an alternative example in which recesses are formed in the ends of the nanostructure channels 315 through the source/drain recesses 305 prior to formation of the source/drain regions 605. FIGS. 8A-8D are each illustrated from a plurality of perspectives illustrated in FIG. 2, including the perspective of the cross-sectional plane A-A in FIG. 2, the perspective of the cross-sectional plane B-B in FIG. 2, and/or the perspective of the cross-sectional plane C-C in FIG. 2.

As shown in the cross-sectional plane A-A, the cross-sectional plane B-B, and the cross-sectional plane C-C in FIG. 8A, the operations described in connection with the example implementation 800 are performed after the operations described in connection with FIGS. 1A-5D.

As shown in the cross-sectional plane B-B in FIG. 8B, cavities 805 are formed in the ends of the nanostructure channels 315 that are exposed through a source/drain recess 305a in the semiconductor device 105. Cavities in the ends of the nanostructure channels 315 that are exposed through a source/drain recess 305b in the semiconductor device 105 may be omitted. The source/drain recess 305a may include a source/drain recess that is formed for a p-type source/drain region, and the source/drain recess 305b may be formed for an n-type source/drain region.

An etch tool may be used to laterally etch the ends of the nanostructure channels 315 in the source/drain recess 305a to form the cavities 805. For example, an etch tool may be used to laterally etch the ends of the nanostructure channels 315 in the source/drain recess 305a using a wet etch technique, a dry etch technique, and/or another suitable etch technique. The cavities 805 may be located between vertically adjacent inner spacers 515a and/or between an inner spacer 515a and a vertically adjacent inner spacer 515b.

As shown in the cross-sectional plane B-B in FIG. 8B, source/drain regions, a CESL 610, and a dielectric layer 615 may be formed in the semiconductor device 105 in a similar manner as described in connection with FIG. 6, except that a p-type source/drain region 605a is formed in the source/drain recess 305a and an n-type source/drain region 605b is formed in the source/drain recess 305b. The p-type source/drain region 605a may be doped with one or more p-type dopants such as boron (B) and/or gallium (Ga), among other examples. The n-type source/drain region 605b may be doped with one or more n-type dopants such as phosphorous (P) and/or arsenic (As), among other examples.

As further shown in FIG. 8C, a liner 810 may be included on sides of the p-type source/drain region 605a between the p-type source/drain region 605a and the nanostructure channels 315, and between the p-type source/drain region 605a and the inner spacers 515a and 515b. The liner 810 may be included around the p-type source/drain region 605a to prevent (or minimize) etching into the p-type source/drain region 605a when removing the inner spacers 515a and 515b to form the air gaps 720a and 720b. The liner 810 may be conformally deposited (e.g., by ALD or CVD, among other examples) such that the liner 810 conforms to the profile and contours of the source/drain recess 305a. In particular, the liner 810 conforms to the shape of the cavities 805 such that the liner 810 extends along a portion of the tops and bottoms of the inner spacers 515a and 515b in extension portions 815. The p-type source/drain region 605a also extends into the extension portions 815.

The liner 810 may include a semiconductor liner (e.g., a silicon (Si) liner and/or another type of liner that includes one or more semiconductor materials). In some implementations, the liner 810 includes an undoped semiconductor material (e.g., undoped silicon or undoped silicon germanium (SiGe)). In some implementations, the liner 810 includes a semiconductor material (e.g., silicon or silicon germanium (SiGe)) doped with one or more types of dopants. For example, the liner 810 may be doped with one or more p-type dopants such as boron (B) and/or gallium (Ga), among other examples, for lowering the resistance of the liner 810. In some implementations, a dopant concentration in the liner 810 may be included in a range of approximately 1×10¹⁷ ions per cubic centimeter (ions/cm³) to approximately 5×10²² ions/cm³. However, other values for the range are within the scope of the present disclosure.

In some implementations, a thickness of the liner 810 is included in a range of approximately 0.5 nanometers to approximately 10 nanometers. If the thickness of the liner 810 is less than approximately 0.5 nanometers, the thickness of the liner 810 may be insufficient to prevent etching into the p-type source/drain region 605a. If the thickness of the liner 810 is greater than approximately 10 nanometers, the liner 810 reduces the size of the p-type source/drain region 605a because of less space in the source/drain recess 305a for the p-type source/drain region 605a. This may result in increased contact resistance for the p-type source/drain region 605a. If the thickness of the liner 810 is included in the range of approximately 0.5 nanometers to approximately 10 nanometers, the liner 810 may prevent the p-type source/drain region 605a from being etched while enabling a sufficiently low contact resistance to be achieved for the p-type source/drain region 605a. However, other values and ranges for the thickness of the liner 810 are within the scope of the present disclosure.

As shown in the cross-sectional plane B-B in FIG. 8D, similar operations as described in connection with FIGS. 7A-7D may be performed to form the air gaps 720a and 720b, as well as the gate structures 725. The liner 810 and the p-type source/drain region 605a in the extension portions 815 are included on top and bottom sides of the air gaps 720a and on the top sides of the air gap 720b. Moreover, the p-type source/drain region 605a and/or the n-type source/drain region 605b has a rounded bottom surface. The liner 810 may conform to the rounded bottom surface of the p-type source/drain region 605a in implementations in which the p-type source/drain region 605a has a rounded bottom surface. The liner 810 is spaced apart from the underlying buffer region 505 by the air gap 720b.

As indicated above, FIGS. 8A-8D are provided as an example. Other examples may differ from what is described with regard to FIGS. 8A-8D.

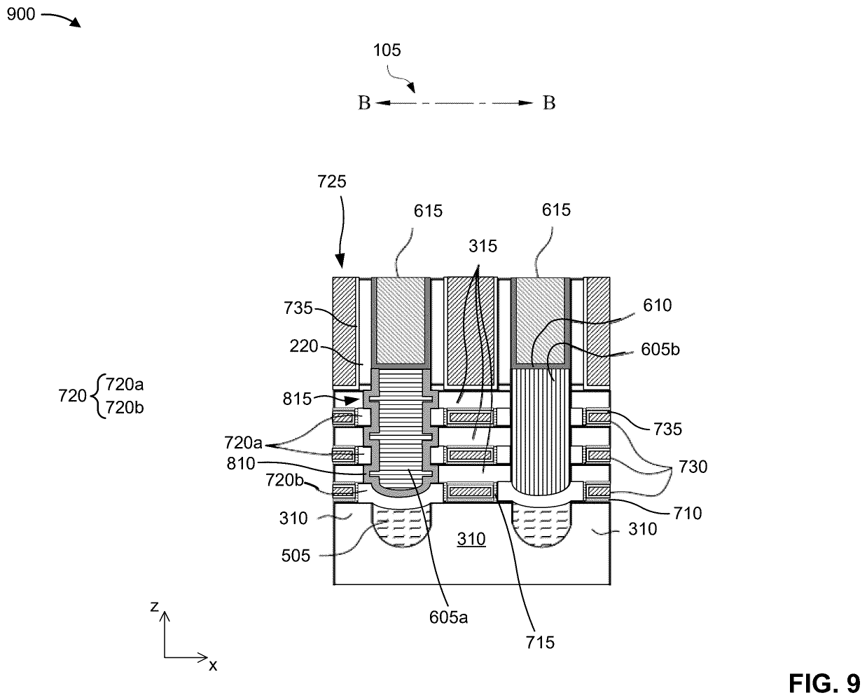

FIG. 9 is a diagram of an example implementation 900 of the semiconductor device 105 described herein. The example implementation 900 of the semiconductor device 105 is similar to the example illustrated in FIG. 8D, except that the top surfaces of the buffer regions 505 under the p-type source/drain region 605a and/or under the n-type source/drain region 605b are curved or arc-shaped such that the top surfaces of the buffer regions 505 under the p-type source/drain region 605a and/or under the n-type source/drain region 605b are recessed below the top surfaces of the adjacent mesa region 310.

As indicated above, FIG. 9 is provided as an example. Other examples may differ from what is described with regard to FIG. 9.

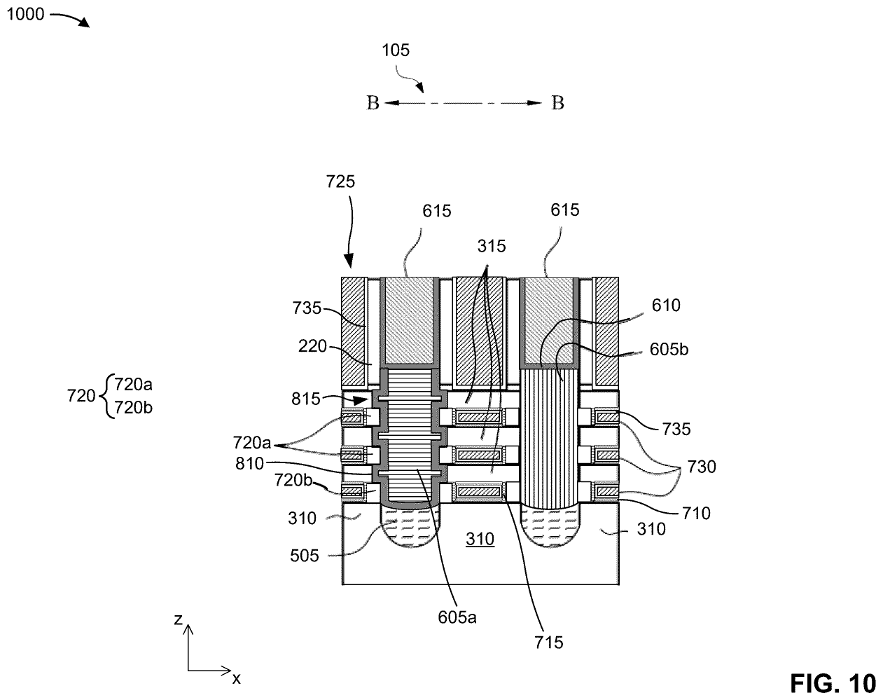

FIG. 10 is a diagram of an example implementation 1000 of the semiconductor device 105 described herein. The example implementation 1000 of the semiconductor device 105 is similar to the example illustrated in FIG. 9, except that the liner 810 is in physical contact with the curved or arc-shaped top surface of the underlying buffer region 505 and the bottom surface of the n-type source/drain region 605b is in physical contact with the curved or arc-shaped top surface of the underlying buffer region 505. Thus, air gaps 720b are located on opposing sides of the p-type source/drain region 605a and not between the p-type source/drain region 605a and the underlying buffer region 505. Moreover, air gaps 720b are located on opposing sides of the n-type source/drain region 605b and not between the n-type source/drain region 605b and the underlying buffer region 505.

As indicated above, FIG. 10 is provided as an example. Other examples may differ from what is described with regard to FIG. 10.

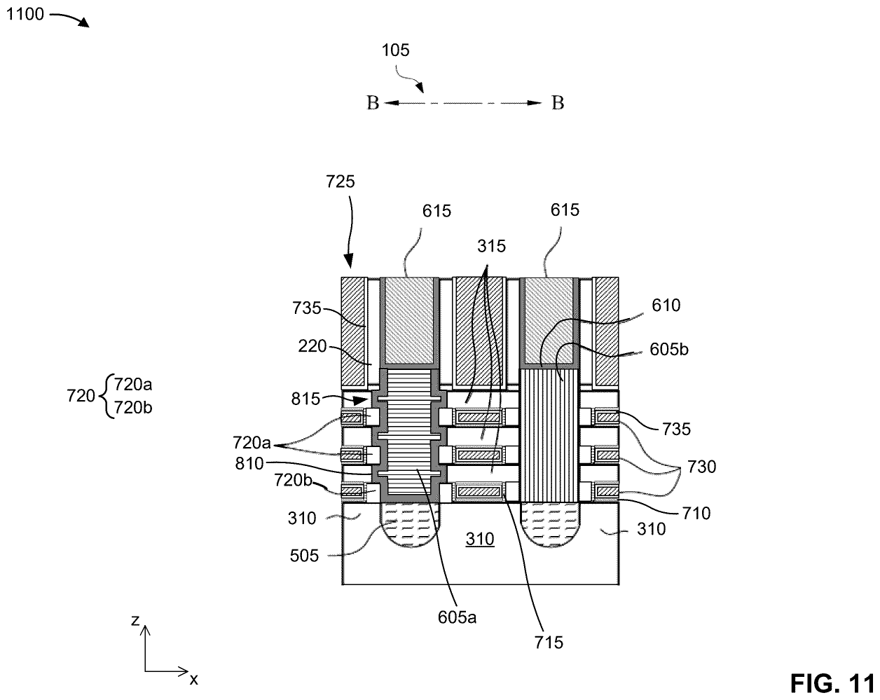

FIG. 11 is a diagram of an example implementation 1100 of the semiconductor device 105 described herein. The example implementation 1100 of the semiconductor device 105 is similar to the example illustrated in FIG. 10, except that the bottom surface of the p-type source/drain region 605a and the top surface of the underlying buffer region 505 are substantially flat. Additionally and/or alternatively, the bottom surface of the n-type source/drain region 605b and the top surface of the underlying buffer region 505 are substantially flat. The top surfaces of the buffer regions 505 under the p-type source/drain region 605a and/or under the n-type source/drain region 605b may be approximately co-planar with the top surfaces of the adjacent mesa regions 310.

As indicated above, FIG. 11 is provided as an example. Other examples may differ from what is described with regard to FIG. 11.

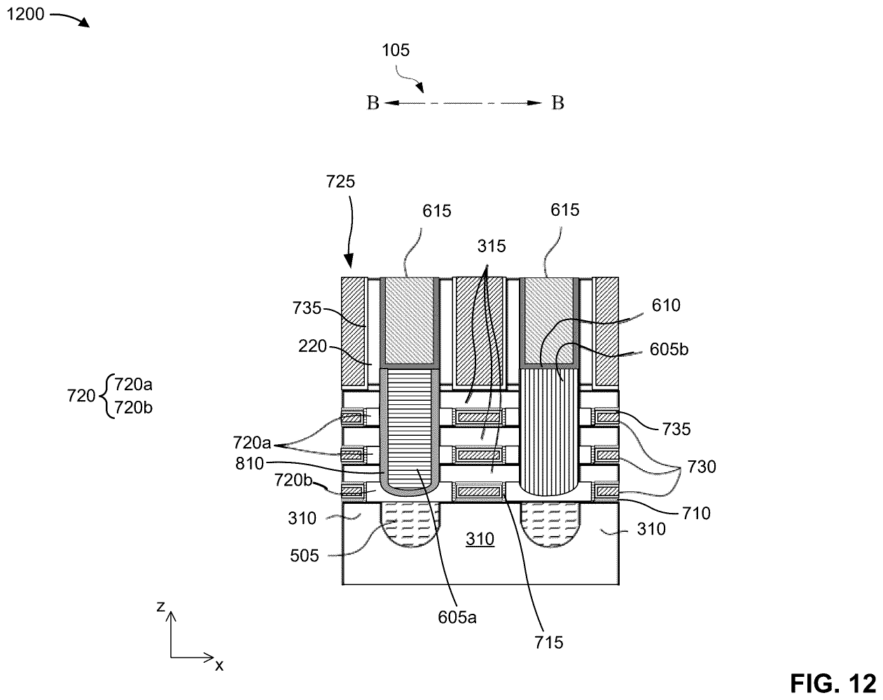

FIG. 12 is a diagram of an example implementation 1200 of the semiconductor device 105 described herein. The example implementation 1200 of the semiconductor device 105 is similar to the example illustrated in FIG. 8D, except that the extension portions 815 are omitted from the liner 810 and the p-type source/drain region 605a. Instead, the sidewalls of the p-type source/drain region 605a (and the liner 810 on the sidewalls) extend in an approximately straight-lined manner between a top and a bottom of the p-type source/drain region 605a.

As indicated above, FIG. 12 is provided as an example. Other examples may differ from what is described with regard to FIG. 12.

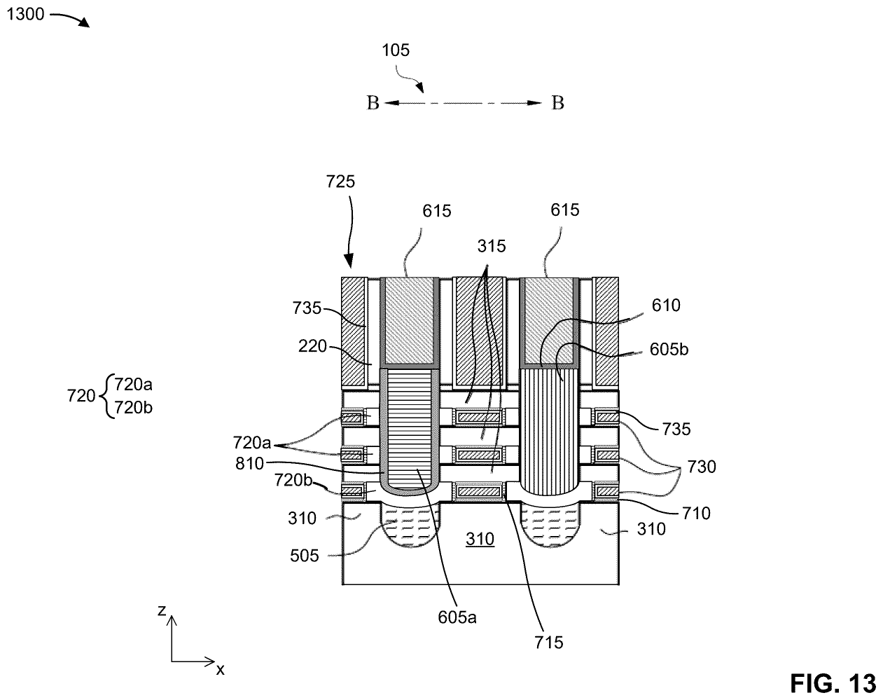

FIG. 13 is a diagram of an example implementation 1300 of the semiconductor device 105 described herein. The example implementation 1300 of the semiconductor device 105 is similar to the example illustrated in FIG. 12, except that the top surfaces of the buffer regions 505 under the p-type source/drain region 605a and/or under the n-type source/drain region 605b are curved or arc-shaped such that the top surfaces of the buffer regions 505 under the p-type source/drain region 605a and/or under the n-type source/drain region 605b are recessed below the top surfaces of the adjacent mesa region 310.

As indicated above, FIG. 13 is provided as an example. Other examples may differ from what is described with regard to FIG. 13.

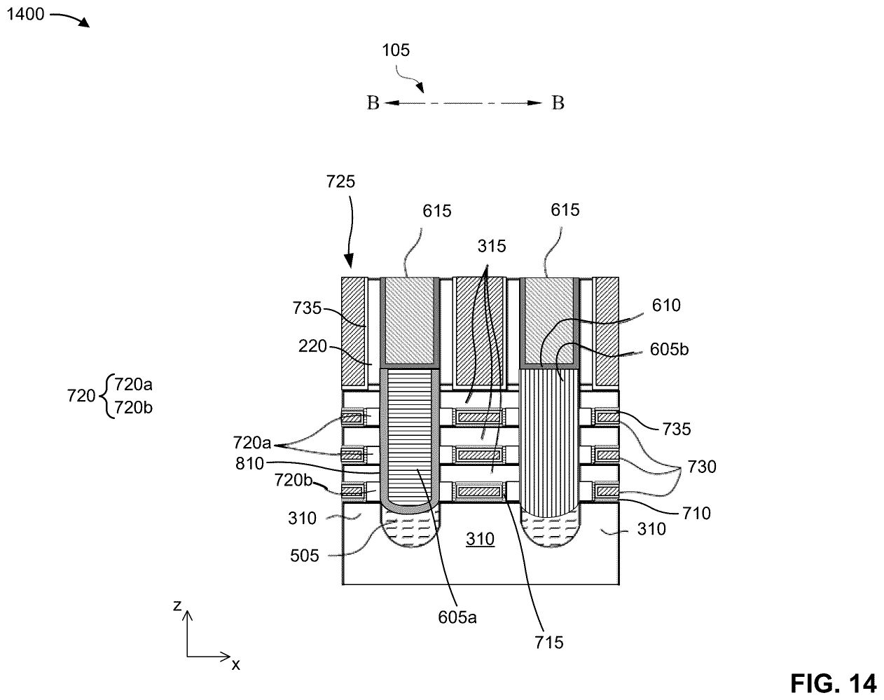

FIG. 14 is a diagram of an example implementation 1400 of the semiconductor device 105 described herein. The example implementation 1400 of the semiconductor device 105 is similar to the example illustrated in FIG. 13, except that the liner 810 is in physical contact with the curved or arc-shaped top surface of the underlying buffer region 505 and the bottom surface of the n-type source/drain region 605b is in physical contact with the curved or arc-shaped top surface of the underlying buffer region 505. Thus, air gaps 720b are located on opposing sides of the p-type source/drain region 605a and not between the p-type source/drain region 605a and the underlying buffer region 505. Moreover, air gaps 720b are located on opposing sides of the n-type source/drain region 605b and not between the n-type source/drain region 605b and the underlying buffer region 505.

As indicated above, FIG. 14 is provided as an example. Other examples may differ from what is described with regard to FIG. 14.

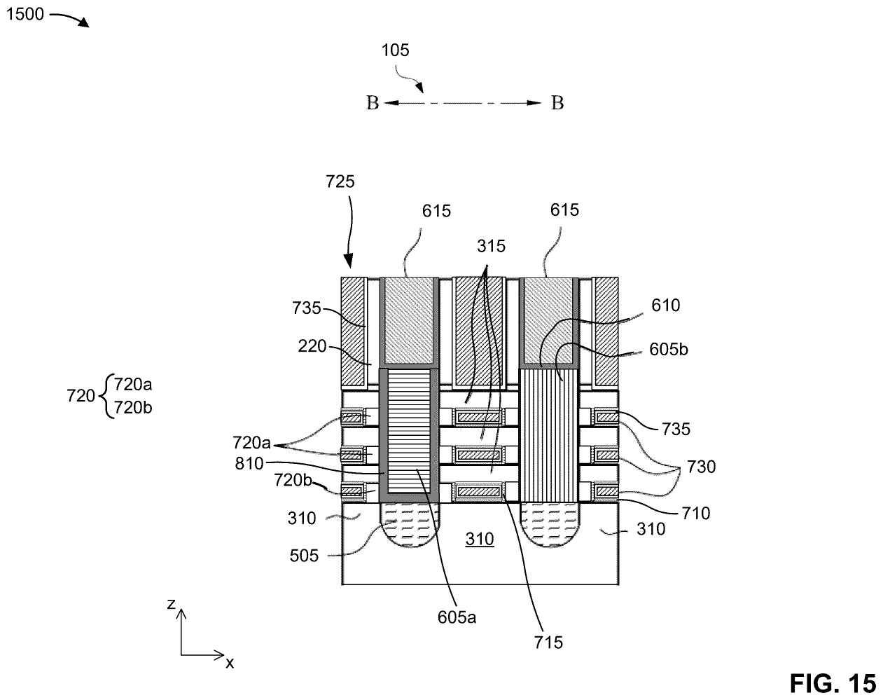

FIG. 15 is a diagram of an example implementation 1500 of the semiconductor device 105 described herein. The example implementation 1500 of the semiconductor device 105 is similar to the example illustrated in FIG. 14, except that the bottom surface of the p-type source/drain region 605a and the top surface of the underlying buffer region 505 are substantially flat. Additionally and/or alternatively, the bottom surface of the n-type source/drain region 605b and the top surface of the underlying buffer region 505 are substantially flat. The top surfaces of the buffer regions 505 under the p-type source/drain region 605a and/or under the n-type source/drain region 605b may be approximately co-planar with the top surfaces of the adjacent mesa regions 310.

As indicated above, FIG. 15 is provided as an example. Other examples may differ from what is described with regard to FIG. 15.

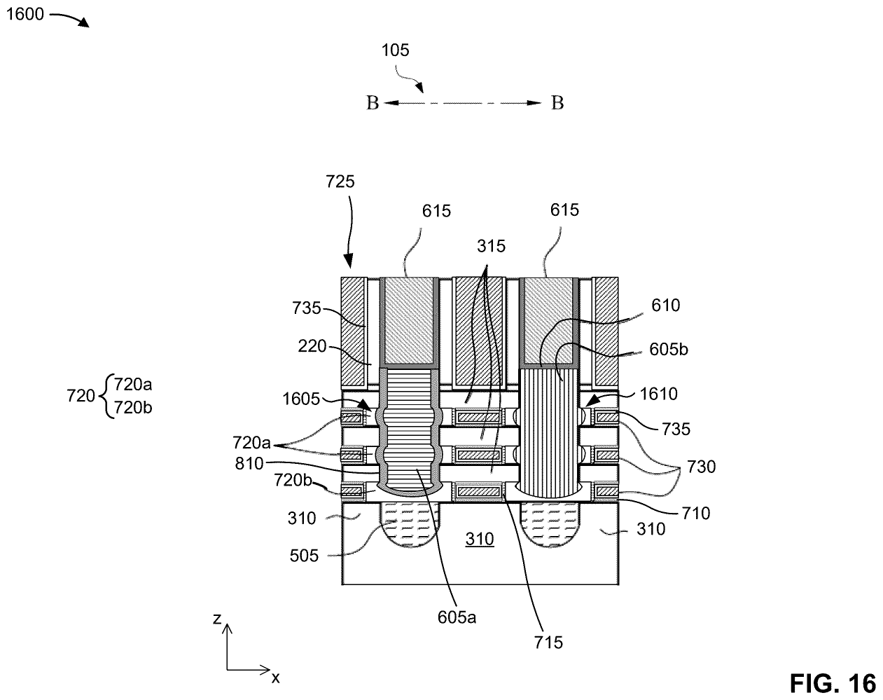

FIG. 16 is a diagram of an example implementation 1600 of the semiconductor device 105 described herein. The example implementation 1600 of the semiconductor device 105 is similar to the example illustrated in FIG. 12, except that sides of the p-type source/drain region 605a includes convex protrusions 1605 that extend laterally outward from the sidewalls of the p-type source/drain region 605a and into portions of the air gaps 720a and/or 720b. The liner 810 may conform to the shape of the sides of the p-type source/drain region 605a and may similarly have the convex protrusions 1605. Additionally and/or alternatively, the sides of the n-type source/drain region 605b include convex protrusions 1610 that extend laterally outward from the sidewalls of the n-type source/drain region 605b and into portions of the air gaps 720a and/or 720b.

The convex protrusions 1605 and 1610 may be referred to as dishing of the air gaps 720a and/or 720b. The convex protrusions 1605 and 1610 may result from formation of the inner spacers 515a and/or 515b. In particular, the convex protrusions 1605 and 1610 may result because of dishing that occurs in the surfaces of the inner spacers 515a and/or 515b when etching or trimming the inner spacer layer 510 to form the inner spacers 515a and/or 515b. The dishing may occur because of over etching of the inner spacers 515a and/or 515b, and the air gaps 720a and/or 720b may conform to the shape of the spaces that were previously occupied by the inner spacers 515a and/or 515b.

As indicated above, FIG. 16 is provided as an example. Other examples may differ from what is described with regard to FIG. 16.

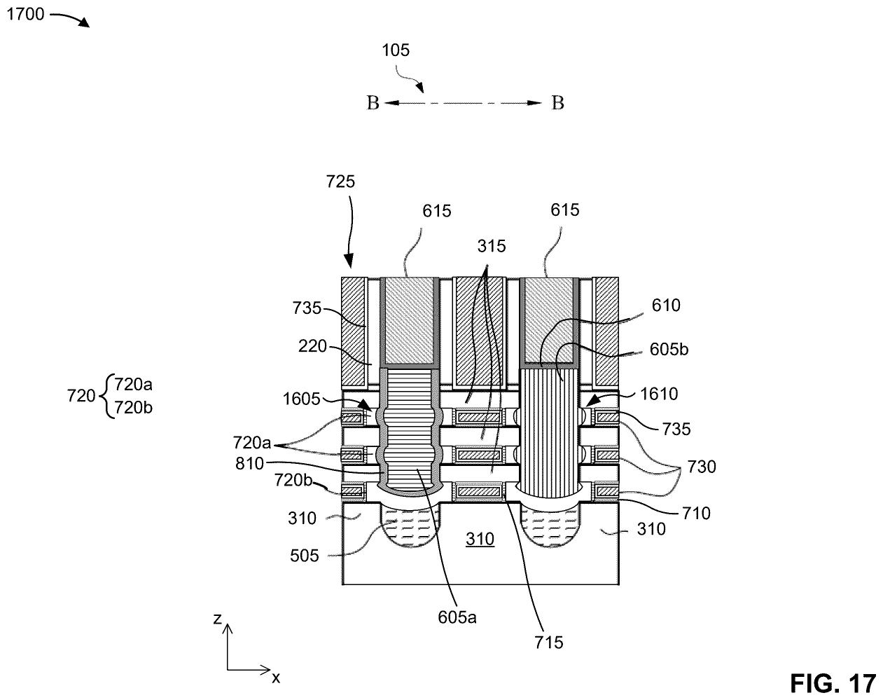

FIG. 17 is a diagram of an example implementation 1700 of the semiconductor device 105 described herein. The example implementation 1700 of the semiconductor device 105 is similar to the example illustrated in FIG. 16, except that the top surfaces of the buffer regions 505 under the p-type source/drain region 605a and/or under the n-type source/drain region 605b are curved or arc-shaped such that the top surfaces of the buffer regions 505 under the p-type source/drain region 605a and/or under the n-type source/drain region 605b are recessed below the top surfaces of the adjacent mesa region 310.

As indicated above, FIG. 17 is provided as an example. Other examples may differ from what is described with regard to FIG. 17.

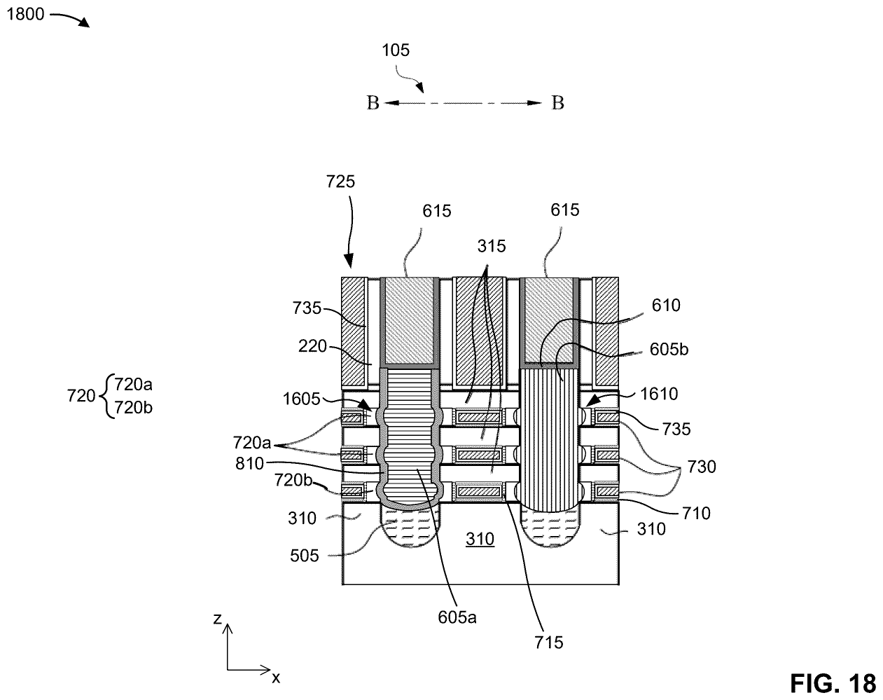

FIG. 18 is a diagram of an example implementation 1800 of the semiconductor device 105 described herein. The example implementation 1800 of the semiconductor device 105 is similar to the example illustrated in FIG. 17, except that the liner 810 is in physical contact with the curved or arc-shaped top surface of the underlying buffer region 505 and the bottom surface of the n-type source/drain region 605b is in physical contact with the curved or arc-shaped top surface of the underlying buffer region 505. Thus, air gaps 720b are located on opposing sides of the p-type source/drain region 605a and not between the p-type source/drain region 605a and the underlying buffer region 505. Moreover, air gaps 720b are located on opposing sides of the n-type source/drain region 605b and not between the n-type source/drain region 605b and the underlying buffer region 505.

As indicated above, FIG. 18 is provided as an example. Other examples may differ from what is described with regard to FIG. 18.

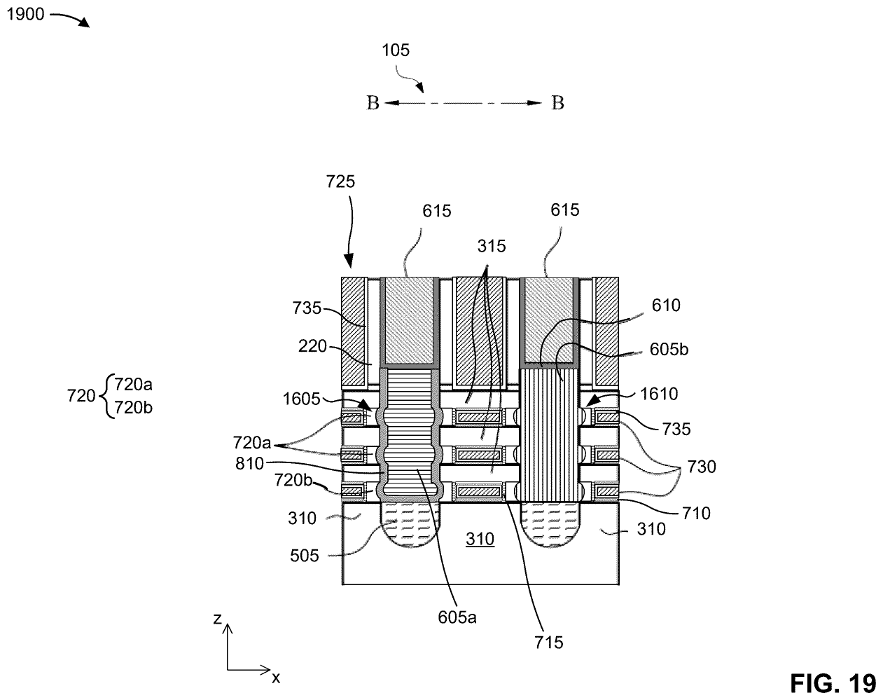

FIG. 19 is a diagram of an example implementation 1900 of the semiconductor device 105 described herein. The example implementation 1900 of the semiconductor device 105 is similar to the example illustrated in FIG. 18, except that the bottom surface of the p-type source/drain region 605a and the top surface of the underlying buffer region 505 are substantially flat. Additionally and/or alternatively, the bottom surface of the n-type source/drain region 605b and the top surface of the underlying buffer region 505 are substantially flat. The top surfaces of the buffer regions 505 under the p-type source/drain region 605a and/or under the n-type source/drain region 605b may be approximately co-planar with the top surfaces of the adjacent mesa regions 310.

As indicated above, FIG. 19 is provided as an example. Other examples may differ from what is described with regard to FIG. 19.

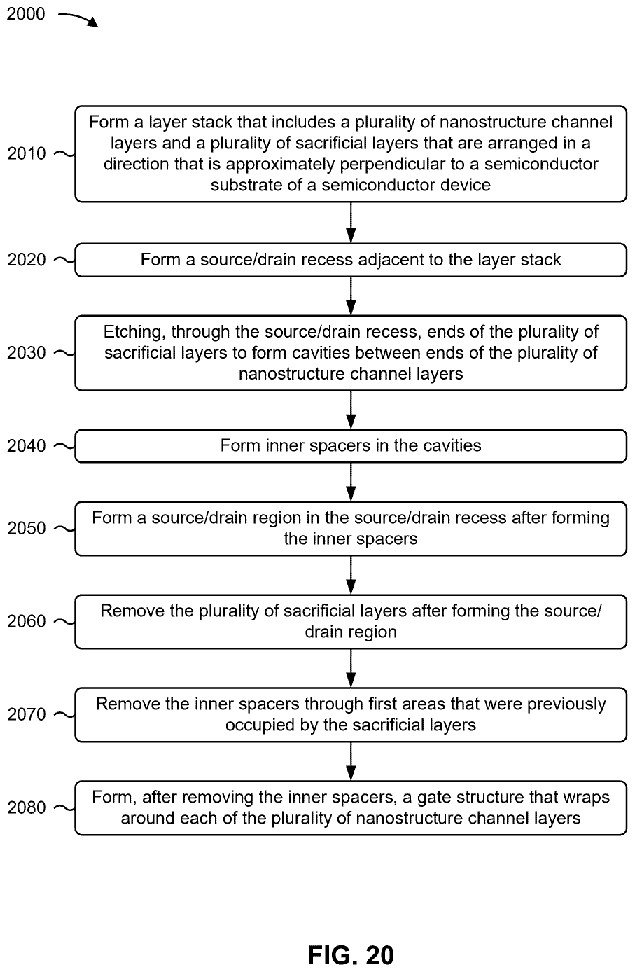

FIG. 20 is a flowchart of an example process 2000 associated with forming a semiconductor device described herein. In some implementations, one or more process blocks of FIG. 20 are performed using one or more semiconductor processing tools, such as a deposition tool, an exposure tool, a developer tool, an etch tool, a planarization tool, an ion implantation tool, and/or another type of semiconductor processing tool.

As shown in FIG. 20, process 2000 may include forming a layer stack that includes a plurality of nanostructure channel layers and a plurality of sacrificial layers that are arranged in a direction that is approximately perpendicular to a semiconductor substrate of a semiconductor device (block 2010). For example, one or more semiconductor processing tools may be used to form a layer stack 115 that includes a plurality of nanostructure channel layers 125 and a plurality of sacrificial nanostructure layers 120 that are arranged in a direction (z-direction) that is approximately perpendicular to a semiconductor substrate 110 of a semiconductor device 105, as described herein.

As further shown in FIG. 20, process 2000 may include forming a source/drain recess adjacent to the layer stack (block 2020). For example, one or more semiconductor processing tools may be used to form a source/drain recess (e.g., a source/drain recess 305, 305a, and/or 305b) adjacent to the layer stack 115, as described herein.

As further shown in FIG. 20, process 2000 may include etching, through the source/drain recess, ends of the plurality of sacrificial layers to form cavities between ends of the plurality of nanostructure channel layers (block 2030). For example, one or more semiconductor processing tools may be used to etch, in the source/drain recess, ends of the plurality of sacrificial nanostructure layers 120 to form cavities 405 between ends of the plurality of nanostructure channel layers 125, as described herein.

As further shown in FIG. 20, process 2000 may include forming inner spacers in the cavities (block 2040). For example, one or more semiconductor processing tools may be used to form inner spacers (e.g., dummy inner spacers 410, inner spacers 515a, inner spacers 515b) in the cavities 405, as described herein.

As further shown in FIG. 20, process 2000 may include forming a source/drain region in the source/drain recess after forming the inner spacers (block 2050). For example, one or more semiconductor processing tools may be used to form a source/drain region (e.g., a source/drain region 605, 605a, and/or 605b) in the source/drain recess after forming the inner spacers, as described herein.

As further shown in FIG. 20, process 2000 may include removing the plurality of sacrificial layers after forming the source/drain region (block 2060). For example, one or more semiconductor processing tools may be used to remove the plurality of sacrificial nanostructure layers 120 after forming the source/drain region, as described herein.

As further shown in FIG. 20, process 2000 may include removing the inner spacers through first areas that were previously occupied by the sacrificial layers (block 2070). For example, one or more semiconductor processing tools may be used to remove the inner spacers through first areas (e.g., openings 705) that were previously occupied by the sacrificial nanostructure layers 120, as described herein.

As further shown in FIG. 20, process 2000 may include forming, after removing the inner spacers, a gate structure that wraps around each of the plurality of nanostructure channel layers (block 2080). For example, one or more semiconductor processing tools may be used to form, after removing the inner spacers, a gate structure 725 that wraps around each of the plurality of nanostructure channels 315 formed from the nanostructure channel layers 125, as described herein. In some implementations, forming the gate structure 725 results in formation of air gaps (e.g., air gaps 720, 720a, and/or 720b) in second areas between the gate structure 725 and the source/drain region that were previously occupied by the inner spacers.

Process 2000 may include additional implementations, such as any single implementation or any combination of implementations described below and/or in connection with one or more other processes described elsewhere herein.

In a first implementation, forming the inner spacers includes forming dummy inner spacers 410 in the cavities 405, removing the dummy inner spacers 410 from the cavities 405 after forming the dummy inner spacers 410, and forming the inner spacers 515a and 515b in the cavities 405 after removing the dummy inner spacers 410.

In a second implementation, alone or in combination with the first implementation, process 2000 includes forming a buffer region 505 at a bottom of the source/drain recess after forming the dummy inner spacers 410, where removing the dummy inner spacers 410 includes removing the dummy inner spacers 410 after forming the buffer region 505.

In a third implementation, alone or in combination with one or more of the first and second implementations, forming the inner spacers includes forming an inner spacer 515b, of the inner spacers, on the buffer region 505, where removal of the inner spacer 515b results in formation of an air gap 720b between the source/drain region and the buffer region 505.

In a fourth implementation, alone or in combination with one or more of the first through third implementations, the dummy inner spacer 410 includes an oxide material.

In a fifth implementation, alone or in combination with one or more of the first through fourth implementations, the dummy inner spacer 410 includes at least one of silicon nitride (SiₓN_{y}), silicon carbonitride (SiCN), or a silicon carbon oxynitride (SiCON).

In a sixth implementation, alone or in combination with one or more of the first through fifth implementations, process 2000 includes forming, after removing the sacrificial layers (e.g., the sacrificial nanostructure layers 120) and prior to removing the inner spacers, a porous interfacial layer 715 on ends of the inner spacers, where removing the inner spacers includes removing the inner spacers through the porous interfacial layer 715.

In a seventh implementation, alone or in combination with one or more of the first through sixth implementations, forming the porous interfacial layer 715 includes oxidizing the ends of the inner spacers to form an oxide layer on the ends of the inner spacers, and performing an electrochemical etch of the oxide layer to form pores in the oxide layer to form the porous interfacial layer 715.

In an eighth implementation, alone or in combination with one or more of the first through seventh implementations, forming the gate structure 725 includes forming the gate structure 725 on the porous interfacial layer 715, where the porous interfacial layer 715 inhibits formation of the gate structure 725 in the air gaps.

Although FIG. 20 shows example blocks of process 2000, in some implementations, process 2000 includes additional blocks, fewer blocks, different blocks, or differently arranged blocks than those depicted in FIG. 20. Additionally, or alternatively, two or more of the blocks of process 2000 may be performed in parallel.

FIGS. 21A-21E are diagrams of an example implementation 2100 of an inner spacer formation process described herein. The example implementation 2100 includes an example of forming the inner spacers 515 without the use of dummy inner spacers 410. This may reduce the processing complexity, processing time, and/or processing cost of forming the inner spacers 515. However, the processes illustrated in FIGS. 4A, 4B, and 5A-5D may enable minimal to no etching of the buffer regions 505 to be achieved because the cavities 405 are formed prior to formation of the buffer regions 505 in the processes illustrated in FIGS. 4A, 4B, and 5A-5D.

FIGS. 21A-21D are each illustrated from a plurality of perspectives illustrated in FIG. 2, including the perspective of the cross-sectional plane A-A in FIG. 2, the perspective of the cross-sectional plane B-B in FIG. 2, and/or the perspective of the cross-sectional plane C-C in FIG. 2.

As shown in the cross-sectional plane A-A and the cross-sectional plane B-B in FIG. 21A, the operations described in connection with the example implementation 2100 are performed after the processes described in connection with FIGS. 1A-3.

As shown in the cross-sectional plane A-A and the cross-sectional plane B-B in FIG. 21B, a deposition tool may be used to deposit the buffer regions 505 at the bottom of the source/drain recesses 305. The buffer regions 505 may be formed prior to formation of the cavities 405 and without the use of dummy inner spacers 410.

As shown in the cross-sectional plane B-B in FIG. 21C, the ends of the sacrificial nanostructure layers 120 that are exposed in the source/drain recesses 305 are laterally etched (e.g., in the y-direction that is approximately parallel to a length of the sacrificial nanostructure layers 120) in an etch operation, thereby forming cavities 405 between the ends of the nanostructure channels 315 that are exposed in the source/drain recesses 305. The cavities 405 may be formed after formation of the buffer regions 505 in the source/drain recesses 305.

As shown in the cross-sectional plane B-B in FIG. 21D, a deposition tool may be used to deposit an inner spacer layer 510 in the cavities 405 and along the sidewalls and bottom surface of the source/drain recesses 305. A CVD technique, a PVD technique, and ALD technique, an epitaxy technique, and/or another deposition technique may be used to deposit the layer of dielectric material.

As shown in the cross-sectional plane B-B in FIG. 21E, inner spacers 515 are formed in the cavities 405 between the ends of vertically adjacent nanostructure channels 315 in the source/drain recesses 305. The inner spacers 515 are included to protect source/drain regions (that are subsequently formed in the source/drain recesses 305) from being etched in a nanosheet release operation to remove the sacrificial nanostructure layers 120 between the nanostructure channels 315. An etch tool is used to remove excess material of the inner spacer layer 510 (e.g., may be used to trim the inner spacer layer 510 using a dry etch technique, a wet etch technique) from the source/drain recesses 305 such that remaining portions correspond to the inner spacers 515 in the cavities 405.

As indicated above, FIGS. 21A-21E are provided as an example. Other examples may differ from what is described with regard to FIGS. 21A-21E.

In this way, inner spacers between a source/drain region of a nanostructure transistor and sacrificial nanostructure layers of the nanostructure transistor are removed prior to formation of a gate structure of the nanostructure transistor. The sacrificial nanostructure layers are removed, and then the inner spacers are removed. The sacrificial nanostructure layers are then replaced with the gate structure of the nanostructure transistor such that the gate structure and the source/drain region are spaced apart by air gaps that result from the removal of the inner spacers. The dielectric constant (or relative permittivity) of the air gaps between the source/drain region and the gate structure is less than the dielectric constant of the material of the inner spacers. The lesser dielectric constant of the air gaps reduces the amount of capacitance between the source/drain region and the gate structure.

As described in greater detail above, some implementations described herein provide a semiconductor device. The semiconductor device includes a plurality of nanostructure channels that are arranged in a direction that is approximately perpendicular to a semiconductor substrate of the semiconductor device. The semiconductor device includes a gate structure wrapping around each of the plurality of nanostructure channels. The semiconductor device includes a source/drain region adjacent to ends of the plurality of nanostructure channels and ends of the gate structure, where the source/drain region and the ends of the gate structure are spaced apart by a plurality of air gaps.

As described in greater detail above, some implementations described herein provide a semiconductor device. The semiconductor device includes a plurality of nanostructure channels that are arranged in a direction that is approximately perpendicular to a semiconductor substrate of the semiconductor device. The semiconductor device includes a gate structure wrapping around each of the plurality of nanostructure channels. The semiconductor device includes a source/drain region adjacent to ends of the plurality of nanostructure channels and ends of the gate structure, where the source/drain region and the ends of the gate structure are spaced apart by a plurality of air gaps. The semiconductor device includes a buffer region under the source/drain region and adjacent to a mesa region that is under the gate structure, where the buffer region comprises a semiconductor material, and where the buffer region and the source/drain region are spaced apart by an air gap of the plurality of air gaps.

As described in greater detail above, some implementations described herein provide a method. The method includes forming a layer stack that includes a plurality of nanostructure channel layers and a plurality of sacrificial layers that are arranged in a direction that is approximately perpendicular to a semiconductor substrate of a semiconductor device. The method includes forming a source/drain recess adjacent to the layer stack. The method includes etching, through the source/drain recess, ends of the plurality of sacrificial layers to form cavities between ends of the plurality of nanostructure channel layers. The method includes forming inner spacers in the cavities. The method includes forming a source/drain region in the source/drain recess after forming the inner spacers. The method includes removing the plurality of sacrificial layers after forming the source/drain region. The method includes removing the inner spacers through first areas that were previously occupied by the sacrificial layers. The method includes forming, after removing the inner spacers, a gate structure that wraps around each of the plurality of nanostructure channel layers, where forming the gate structure results in formation of air gaps in second areas between the gate structure and the source/drain region that were previously occupied by the inner spacers.

The terms “approximately” and “substantially” can indicate a value of a given quantity that varies within 5% of the value (e.g., ±1%, ±2%, ±3%, ±4%, +5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a plurality of nanostructure channels that are arranged in a direction that is approximately perpendicular to a semiconductor substrate of the semiconductor device;
a gate structure wrapping around each of the plurality of nanostructure channels; and
a source/drain region adjacent to ends of the plurality of nanostructure channels and ends of the gate structure,
wherein the source/drain region and the ends of the gate structure are spaced apart by a plurality of air gaps.

2. The semiconductor device of claim 1, wherein the source/drain region is in direct contact with the ends of the plurality of nanostructure channels.

3. The semiconductor device of claim 1, further comprising:
a liner between the source/drain region and the ends of the plurality of nanostructure channels,
wherein the liner includes a semiconductor material.

4. The semiconductor device of claim 3, wherein the semiconductor material of the liner is doped with one or more p-type dopants.

5. The semiconductor device of claim 3, wherein a thickness of the liner is included in a range of approximately 0.5 nanometers to approximately 10 nanometers.

6. The semiconductor device of claim 3, wherein extension portions of the liner are included on sides of the plurality of air gaps.

7. The semiconductor device of claim 1, wherein sides of the source/drain region comprise convex protrusions that extend into portions of the plurality of air gaps.

8. A semiconductor device, comprising:
a plurality of nanostructure channels that are arranged in a direction that is approximately perpendicular to a semiconductor substrate of the semiconductor device;
a gate structure wrapping around each of the plurality of nanostructure channels;
a source/drain region adjacent to ends of the plurality of nanostructure channels and ends of the gate structure,
wherein the source/drain region and the ends of the gate structure are spaced apart by a plurality of air gaps; and
a buffer region under the source/drain region and adjacent to a mesa region that is under the gate structure,
wherein the buffer region comprises a semiconductor material, and
wherein the buffer region and the source/drain region are spaced apart by an air gap of the plurality of air gaps.

9. The semiconductor device of claim 8, wherein a top surface of the buffer region and a top surface of the mesa region are approximately co-planar.

10. The semiconductor device of claim 8, wherein a top surface of the buffer region is recessed below a top surface of the mesa region.

11. The semiconductor device of claim 8, wherein a bottom surface of the source/drain region, facing the buffer region, has a curved cross-sectional profile.

12. The semiconductor device of claim 8, further comprising:
a porous interfacial layer between the air gap and the gate structure.

13. The semiconductor device of claim 8, wherein the source/drain region comprises a p-type source/drain region; and
wherein the semiconductor device further comprises:
a liner between the source/drain region and the air gap,
wherein the liner comprises at least one of silicon (Si) or silicon germanium (SiGe).

14. The semiconductor device of claim 13, wherein the liner is doped with at least one of boron (B) or gallium (Ga).

15. A method, comprising:
forming a layer stack that includes a plurality of nanostructure channel layers and a plurality of sacrificial layers that are arranged in a direction that is approximately perpendicular to a semiconductor substrate of a semiconductor device;
forming a source/drain recess adjacent to the layer stack;
etching, through the source/drain recess, ends of the plurality of sacrificial layers to form cavities between ends of the plurality of nanostructure channel layers;
forming inner spacers in the cavities;
forming a source/drain region in the source/drain recess after forming the inner spacers;
removing the plurality of sacrificial layers after forming the source/drain region;
removing the inner spacers through first areas that were previously occupied by the sacrificial layers; and
forming, after removing the inner spacers, a gate structure that wraps around each of the plurality of nanostructure channel layers,
wherein forming the gate structure results in formation of air gaps in second areas between the gate structure and the source/drain region that were previously occupied by the inner spacers.

16. The method of claim 15, wherein forming the inner spacers comprises:
forming dummy inner spacers in the cavities;
removing the dummy inner spacers from the cavities after forming the dummy inner spacers; and
forming the inner spacers in the cavities after removing the dummy inner spacers.

17. The method of claim 16, further comprising:
forming a buffer region at a bottom of the source/drain recess after forming the dummy inner spacers,
wherein removing the dummy inner spacers comprises:
removing the dummy inner spacers after forming the buffer region.

18. The method of claim 16, further comprising:
forming, after removing the sacrificial layers and prior to removing the inner spacers, a porous interfacial layer on ends of the inner spacers,
wherein removing the inner spacers comprises:
removing the inner spacers through the porous interfacial layer.

19. The method of claim 18, wherein forming the porous interfacial layer comprises:
oxidizing the ends of the inner spacers to form an oxide layer on the ends of the inner spacers; and
performing an electrochemical etch of the oxide layer to form pores in the oxide layer to form the porous interfacial layer.

20. The method of claim 18, wherein forming the gate structure comprises:
forming the gate structure on the porous interfacial layer,
wherein the porous interfacial layer inhibits formation of the gate structure in the air gaps.
